(19) United States
(12) Patent Application Publication
(10) Pub. No.: US 2026/0141927 A1
(43) Pub. Date: May 21, 2026

(54) THREE-DIMENSIONAL MEMORY DEVICE

(71) Applicant: SK hynix Inc., Icheon-si (KR)

(72) Inventor: Chang Woo KANG, Icheon-si (KR)

(21) Appl. No.: 19/174,624

(22) Filed: Apr. 9, 2025

(30) Foreign Application Priority Data
Nov. 19, 2024 (KR) 10-2024-0165423

(51) Int. Cl. G11C 5/06; H01L 23/00; H01L 25/18; H10B 41/10; H10B 41/27; H10B 41/40; H10B 43/10; H10B 43/27; H10B 43/40; H10B 80/00; H10D 80/30

(52) U.S. Cl. CPC G11C 5/063; H10B 41/10; H10B 41/27; H10B 41/40; H10B 43/10; H10B 43/27; H10B 43/40; H10B 80/00; H10D 80/30; H10W 90/00; H10W 90/20; H10W 90/792

(57) ABSTRACT

A memory device includes a substrate including first and second connection regions arranged in a first horizontal direction; an electrode structure including word lines vertically stacked on the substrate and dummy word lines vertically stacked on the word lines; drain select lines disposed in a drain select line layer on the electrode structure, and extending parallel to each other in the first horizontal direction; drain contacts connected to the drain select lines, respectively, in the first connection region; and dummy contacts extending vertically through the drain select lines in the second connection region, and connected to the dummy word lines, respectively, The dummy contacts are disposed in a plurality of rows, arranged in a second horizontal direction that is perpendicular to the first horizontal direction, and dummy contacts connected in common to one of the dummy word lines are disposed in a single row.

### CROSS-REFERENCE TO RELATED APPLICATION

The present application claims priority under 35 U.S.C. § 119(a) to Korean Patent Application No. 10-2024-0165423 filed in the Korean Intellectual Property Office on Nov. 19, 2024, which is incorporated herein by reference in its entirety.

### BACKGROUND

### 1. Technical Field

The present disclosure relates to semiconductor technology, and more particularly, to three-dimensional memory devices.

### 2. Related Art

Memory devices with two-dimensional or planar structures have been developed to be able to store more data within the same area by using fine patterning processes. However, as a circuit line width narrows due to demands for high integration, interference between memory cells worsens, resulting in various limitations such as deterioration in performance. Of course, in addition to these structural limitations, there is also a problem that expensive equipment should be introduced to pattern fine line widths, which inevitably increases manufacturing costs.

Three-dimensional memory devices have been proposed as an alternative to overcome the limitations of two-dimensional memory devices. The three-dimensional memory devices have advantages in that a larger capacity may be realized within the same area by increasing the number of stacks through stacking memory cells in a vertical direction, thereby providing high performance and excellent power efficiency.

In order to independently apply electrical signals to electrodes located at different heights in three-dimensional memory devices, contacts should be connected to the electrodes, respectively, and various technologies for this purpose are being developed.

### SUMMARY

Embodiments of the present disclosure suggest improved three-dimensional memory devices.

In an embodiment, a memory device may include: a substrate including a first connection region and a second connection region that are arranged in a first horizontal direction; an electrode structure including a plurality of word lines that are vertically stacked on the substrate and a plurality of dummy word lines that are vertically stacked on the plurality of word lines; a plurality of drain select lines extending in the first horizontal direction in a first drain select line layer on the electrode structure; a plurality of drain contacts connected to the plurality of drain select lines, respectively, in the first connection region; and a plurality of dummy contacts extending vertically through the plurality of drain select lines in the second connection region, and connected to the plurality of dummy word lines, respectively, wherein the plurality of dummy contacts are disposed in a plurality of rows, arranged in a second horizontal direction that is perpendicular to the first horizontal direction, and dummy contacts connected in common to one of the plurality of dummy word lines are disposed in a single row parallel to the first horizontal direction.

In an embodiment, a memory device may include: a substrate including a first connection region and a second connection region that are arranged in a first horizontal direction; an electrode structure including a plurality of word lines that are vertically stacked on the substrate and a plurality of dummy word lines that are vertically stacked on the plurality of word lines; a plurality of drain select lines extending parallel to each other in the first horizontal direction in a drain select line layer on the electrode structure, and each including a first pad section that is disposed in the first connection region and a second pad section that is disposed in the second connection region; a plurality of drain contacts connected to first pad sections, respectively, of the plurality of drain select lines; and a plurality of dummy contacts each extending in a vertical direction through one of second pad sections of the plurality of drain select lines, and connected to the plurality of dummy word lines, respectively, wherein the plurality of dummy contacts are disposed in a plurality of rows arranged in a second horizontal direction perpendicular to the first horizontal direction, dummy contacts in each of the plurality of rows are disposed in a line along the first horizontal direction, and at least two of dummy contacts connected in common to one of the plurality of dummy word lines are disposed in one of the plurality of rows.

In an embodiment, a memory device may include: a substrate including a cell region and a connection region that extends in a row direction from the cell region; an electrode structure including a plurality of word lines that are vertically stacked on the substrate and a plurality of dummy word lines that are vertically stacked on the plurality of word lines; a plurality of drain select lines extending in the row direction in a first drain select line layer on the electrode structure, and each including an electrode section that is disposed in the cell region and a pad section that is disposed in the connection region; a plurality of drain contacts connected to pad sections of the plurality of drain select lines, respectively, in the connection region; and a plurality of dummy contacts extending vertically through the pad sections of the plurality of drain select lines in the connection region, and connected to the plurality of dummy word lines, respectively, wherein the plurality of dummy contacts are disposed in a different row from the plurality of drain contacts when viewed in a plan view.

According to embodiments of the present disclosure, because dummy word line connection wirings may be configured to extend in the same direction as drain select line connection wirings, the number of dummy word line connection wirings may be increased without reducing wiring pitch or forming an additional wiring layer. By increasing the number of dummy word line connection wirings, the number of dummy word lines divided by isolation insulating patterns may be increased, and the process margins in the etching processes to form isolation insulating patterns may be improved.

### BRIEF DESCRIPTION OF THE DRAWINGS

FIG. 1 is a plan view of a memory device according to embodiments of the present disclosure.

FIG. 2 is a cross-sectional view taken along a line A-A′ of FIG. 1.

FIG. 3 is a cross-sectional view taken along a line B-B′ of FIG. 1.

FIG. 4 is a cross-sectional view taken along a line C-C′ of FIG. 1.

FIG. 5 is a cross-sectional view taken along a line D-D′ of FIG. 1.

FIG. 6 is a cross-sectional view taken along a line E-E′ of FIG. 1.

FIG. 7 is a cross-sectional view taken along a line F-F′ of FIG. 1.

FIG. 8 is a cross-sectional view taken along a line G-G′ of FIG. 1.

FIG. 9 is a plan view illustrating drain select lines and first, second and third isolation insulating patterns of FIG. 1.

FIG. 10 is a plan view illustrating dummy contacts and dummy word line connection wirings of FIG. 1.

FIG. 11 is a plan view of a memory device according to embodiments of the present disclosure.

FIG. 12 is a plan view illustrating drain contacts and dummy contacts of FIG. 11.

FIG. 13 is a plan view of a memory device according to embodiments of the present disclosure.

FIG. 14 is a plan view illustrating drain contacts and dummy contacts of FIG. 13.

FIG. 15 is a plan view of a memory device according to embodiments of the present disclosure.

FIG. 16 is a plan view illustrating drain select lines and isolation insulating patterns of FIG. 15.

FIG. 17 is a plan view of a memory device according to embodiments of the present disclosure.

FIG. 18 is a cross-sectional view taken along a line H-H′ of FIG. 17.

FIG. 19 is a plan view illustrating drain select lines and isolation insulating patterns of FIG. 17.

FIG. 20 is a plan view illustrating drain contacts, dummy contacts and dummy word line connection wirings of FIG. 17.

FIG. 21 is a plan view of a memory device according to embodiments of the present disclosure.

FIG. 22 is a plan view illustrating drain select lines and isolation insulating patterns of FIG. 21.

FIG. 23 is a cross-sectional view of a memory device according to embodiments of the present disclosure.

### DETAILED DESCRIPTION

Hereinafter, various embodiments of the present disclosure will be described in detail with reference to accompanying drawings. In the following description of examples or embodiments of the present disclosure, reference will be made to the accompanying drawings in which it is shown by way of illustration specific examples or embodiments that can be implemented, and in which the same reference numerals and signs can be used to designate the same or like components, even when they are shown in different accompanying drawings from one another. Further, in the following description of examples or embodiments of the present invention, detailed descriptions of well-known functions and components incorporated herein will be omitted when it is determined that the description may make the subject matter in some embodiments of the present invention more unclear. The terms such as “including”, “having”, “containing”, “constituting” “made up of”, and “formed of” used herein are generally intended to allow other components to be added unless the terms are used with the term “only”. As used herein, singular forms are intended to include plural forms unless the context clearly indicates otherwise.

Terms, such as “first”, “second”, “A”, “B”, “(A)”, or “(B)” may be used herein to describe elements of the present invention. Each of these terms is not used to define essence, order, sequence, or number of elements etc., but is used merely to distinguish the corresponding element from other elements.

When it is mentioned that a first element “is connected or coupled to”, “contacts or overlaps”, etc., a second element, it should be interpreted that, not only can the first element “be directly connected or coupled to” or “directly contact or overlap” the second element, but a third element can also be “interposed” between the first and second elements, or the first and second elements can “be connected or coupled to”, “contact or overlap”, etc. each other via a fourth element. Here, the second element may be included in at least one of two or more elements that “are connected or coupled to”, “contact or overlap”, etc., each other.

When time relative terms, such as “after,” “subsequent to,” “next,” “before,” and the like, are used to describe processes or operations of elements or configurations, or flows or steps in operating, processing, manufacturing methods, these terms may be used to describe non-consecutive or non-sequential processes or operations unless the term “directly” or “immediately” is used together.

In addition, when any dimensions, relative sizes etc., are mentioned, it should be considered that numerical values for elements or features, or corresponding information (e.g., level, range, etc.) include a tolerance or error range that may be caused by various factors (e.g., process factors, internal or external impact, noise, etc.) even when a relevant description is not specified. Further, the term “may” fully encompasses all the meanings of the term “can”.

Hereinafter, it will be described various embodiments of the disclosure in detail with reference to the accompanying drawings.

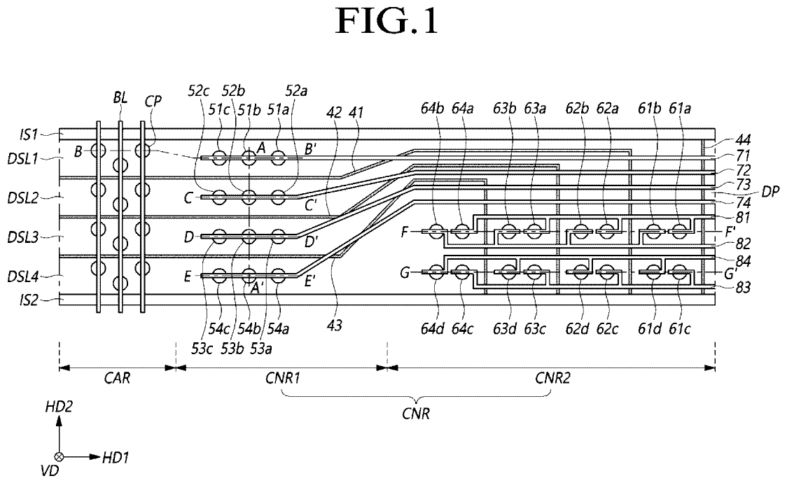

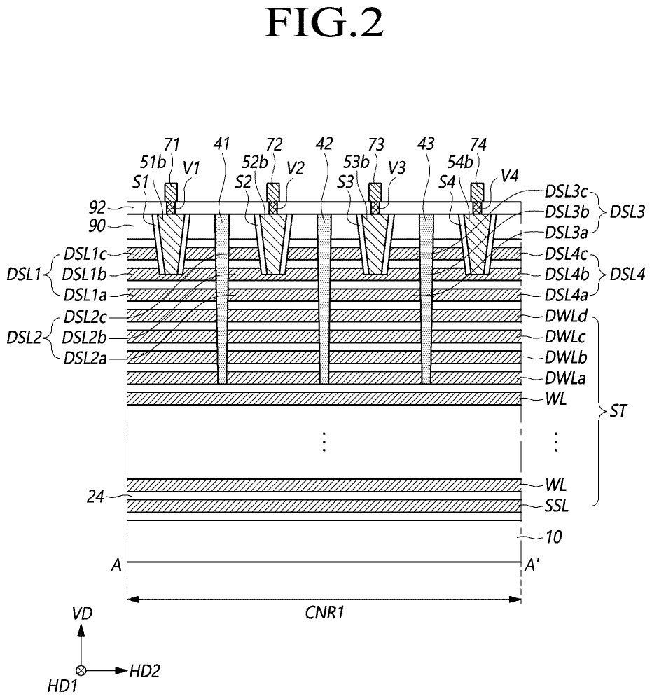

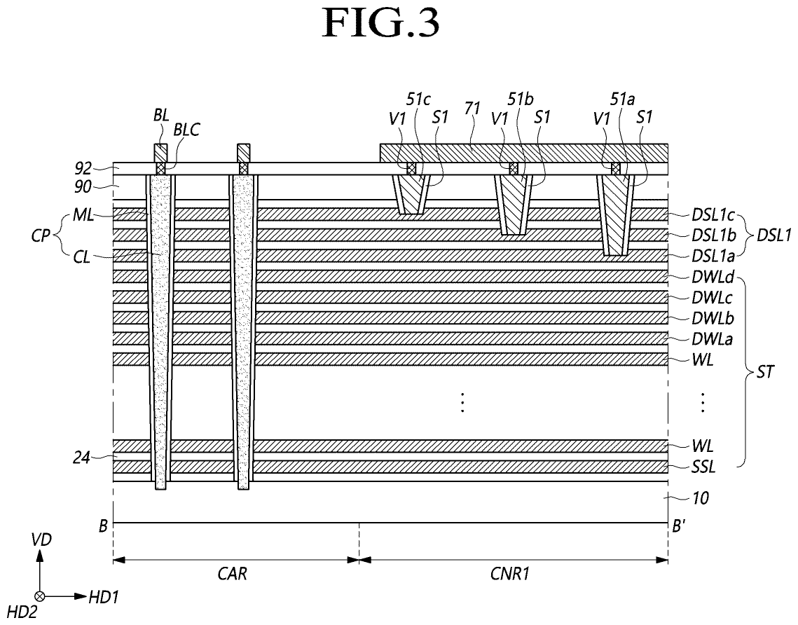

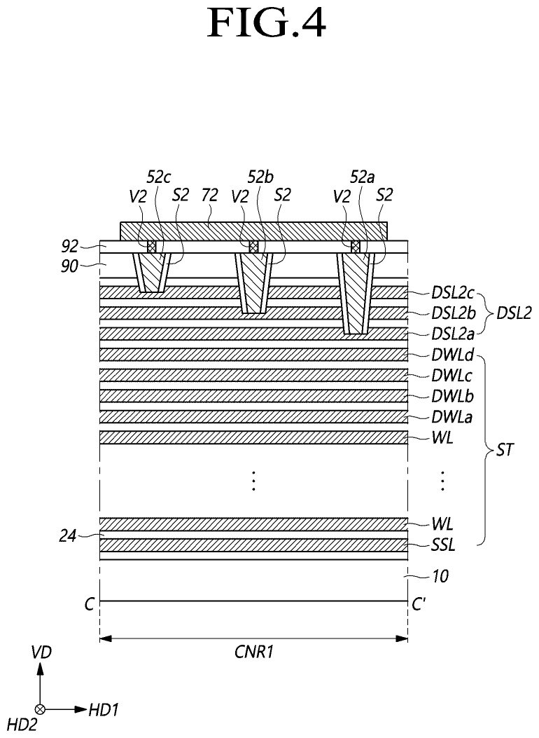

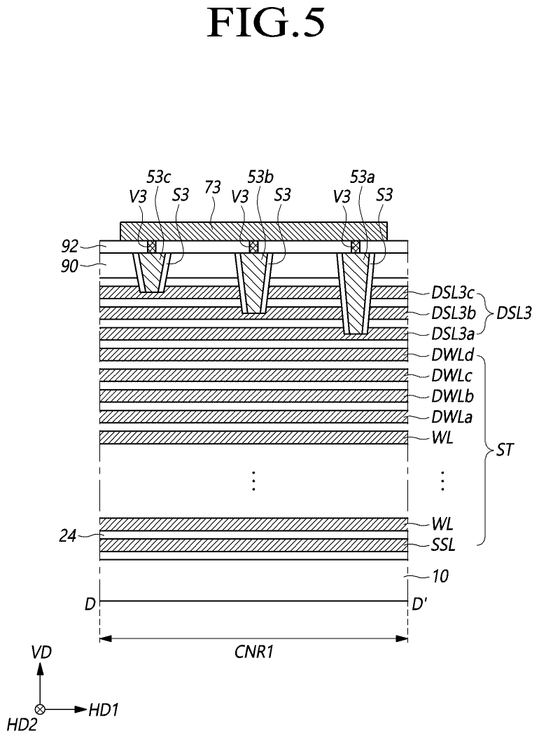

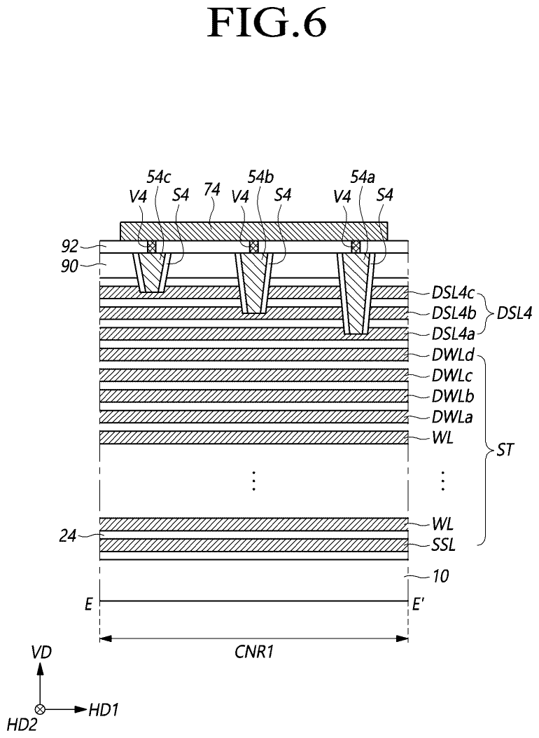

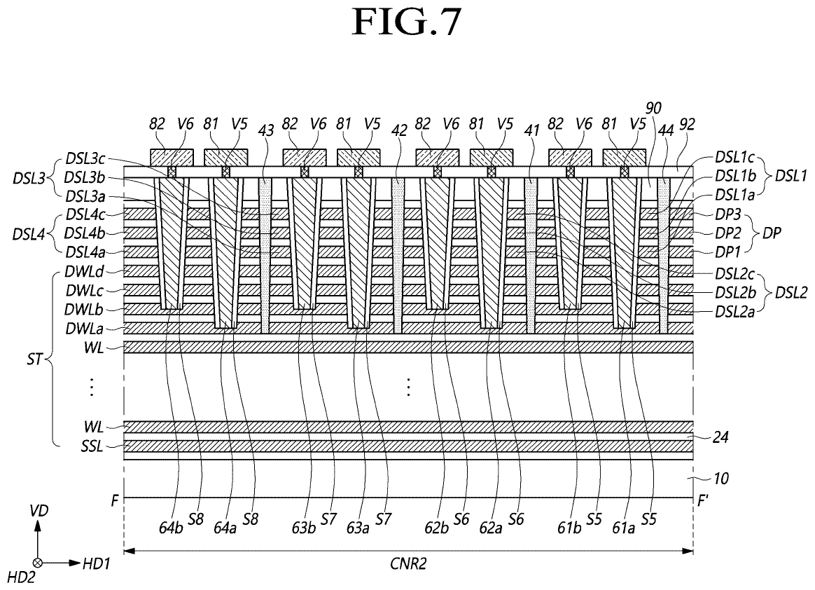

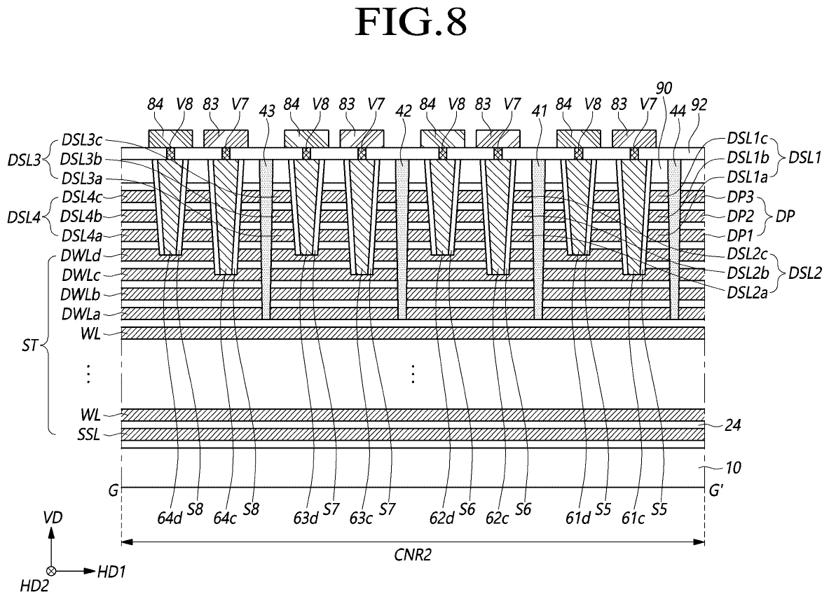

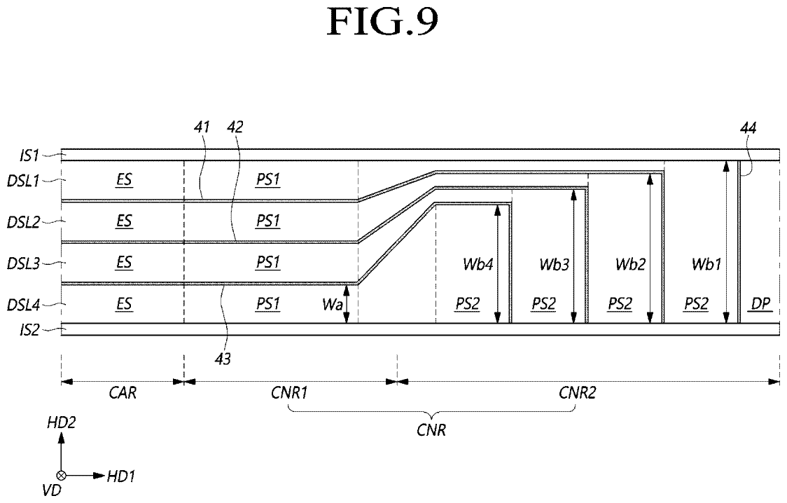

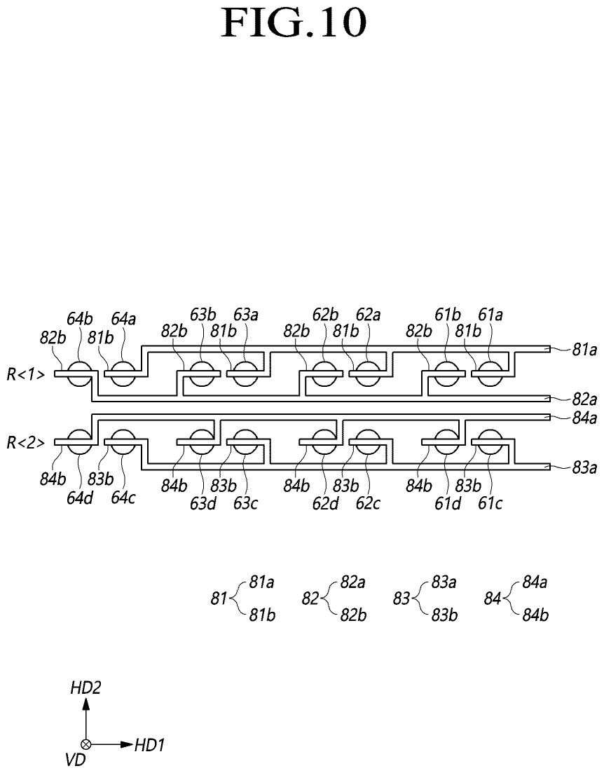

FIG. 1 is a plan view of a memory device according to embodiments of the present disclosure, FIG. 2 is a cross-sectional view taken along a line A-A′ of FIG. 1, FIG. 3 is a cross-sectional view taken along a line B-B′ of FIG. 1, FIG. 4 is a cross-sectional view taken along a line C-C′ of FIG. 1, FIG. 5 is a cross-sectional view taken along a line D-D′ of FIG. 1, FIG. 6 is a cross-sectional view taken along a line E-E′ of FIG. 1, FIG. 7 is a cross-sectional view taken along a line F-F′ of FIG. 1, FIG. 8 is a cross-sectional view taken along a line G-G′ of FIG. 1, FIG. 9 is a plan view illustrating drain select lines and first, second and third isolation insulating patterns of FIG. 1, and FIG. 10 is a plan view illustrating dummy contacts and dummy word line connection wirings of FIG. 1.

Referring to FIG. 1 to FIG. 8, an electrode structure ST is disposed on a substrate 10.

The substrate 10 may be made of a semiconductor material. The semiconductor material may include, for example, at least one of silicon (Si), germanium (Ge), silicon germanium (SiGe), gallium arsenide (GaAs), indium gallium arsenide (InGaAs), aluminum gallium arsenide (AlGaAs) or a combination thereof. The substrate 10 includes a cell region CAR and a connection region CNR that extends from the cell region CAR in a first horizontal direction HD1. The connection region CNR includes a first connection region CNR1 and a second connection region CNR2 that are aligned in the first horizontal direction HD1. The first connection region CNR1 is disposed closer to the cell region CAR than the second connection region CNR2.

The first horizontal direction HD1 may also be defined as a word line direction or a row direction. A second horizontal direction HD2 to be described below, as a direction perpendicular to the first horizontal direction HD1, may also be defined as a bit line direction or a column direction.

The electrode structure ST extends from the cell region CAR to the connection region CNR in the first horizontal direction HD1. The electrode structure ST includes a plurality of word lines WL and a plurality of dummy word lines DWLa, DWLb, DWLc and DWLd. The electrode structure ST may further include a source select line SSL. The source select line SSL may be disposed between a lowermost word line WL, among the plurality of word lines WL, and the substrate 10.

A plurality of drain select lines DSL1, DSL2, DSL3 and DSL4 and a plurality of dummy patterns DP may be disposed on or over the electrode structure ST.

The drain select lines DSL1, DSL2, DSL3 and DSL4 include first drain select lines DSL1, second drain select lines DSL2, third drain select lines DSL3 and fourth drain select lines DSL4.

The first drain select lines DSL1 may include a first lower drain select line DSL1a, a first intermediate drain select line DSL1b on or over the first lower drain select line DSL1a, and a first upper drain select line DSL1c on or over the first intermediate drain select line DSL1b. The second drain select lines DSL2 may include a second lower drain select line DSL2a, a second intermediate drain select line DSL2b on or over the second lower drain select line DSL2a, and a second upper drain select line DSL2c on or over the second intermediate drain select line DSL2b. The third drain select lines DSL3 may include a third lower drain select line DSL3a, a third intermediate drain select line DSL3b on or over the third lower drain select line DSL3a, and a third upper drain select line DSL3c on or over the third intermediate drain select line DSL3b. The fourth drain select lines DSL4 may include a fourth lower drain select line DSL4a, a fourth intermediate drain select line DSL4b on or over the fourth lower drain select line DSL4a, and a fourth upper drain select line DSL4c on or over the fourth intermediate drain select line DSL4b. The dummy patterns DP may include a lower dummy pattern DP1, an intermediate dummy pattern DP2 on or over the lower dummy pattern DP1, and an upper dummy pattern DP3 on or over the intermediate dummy pattern DP2.

The first lower drain select line DSL1a, the second lower drain select line DSL2a, the third lower drain select line DSL3a and the fourth lower drain select line DSL4a are disposed in a lower drain select line layer and extend parallel to each other in the first horizontal direction HD1. The first intermediate drain select line DSL1b, the second intermediate drain select line DSL2b, the third intermediate drain select line DSL3b and the fourth intermediate drain select line DSL4b are disposed in an intermediate drain select line layer and extend parallel to each other in the first horizontal direction HD1. The first upper drain select line DSL1c, the second upper drain select line DSL2c, the third upper drain select line DSL3c and the fourth upper drain select line DSL4c are disposed in an upper drain select line layer and extend parallel to each other in the first horizontal direction HD1.

Although the first, second, third and fourth drain select lines DSL1, DSL2, DSL3 and DSL4 are disposed in three stacked layers, the embodiments of the present disclosure are not limited thereto. Drain select lines may be disposed in only one layer or at least two stacked layers.

The source select line SSL, the word lines WL, the dummy word lines DWLa, DWLb, DWLc and DWLd, the first, second, third and fourth drain select lines DSL1, DSL2, DSL3 and DSL4 and the dummy patterns DP may include a conductive material. The conductive material may include at least one selected among doped semiconductor, metal, conductive metal nitride or transition metal.

The source select line SSL, the word lines WL, the dummy word lines DWLa, DWLb, DWLc and DWLd, the first, second, third and fourth drain select lines DSL1, DSL2, DSL3 and DSL4 and the dummy patterns DP may be stacked alternately with a plurality of interlayer insulating layers 24. The interlayer insulating layers 24 may include silicon oxide.

First and second isolation patterns IS1 and IS2 may be disposed on the substrate 10. The first isolation pattern IS1 and the second isolation pattern IS2 may extend parallel to each other in the first horizontal direction HD1 and may be spaced apart in the second horizontal direction HD2. The electrode structure ST, the first, second, third and fourth drain select lines DSL1, DSL2, DSL3 and DSL4 and the dummy patterns DP may be disposed between the first isolation pattern IS1 and the second isolation pattern IS2. The first and second isolation patterns IS1 and IS2 may contact both side surfaces, respectively, of the electrode structure ST that face away from each other in the second horizontal direction HD2.

The first and second isolation patterns IS1 and IS2 may include an insulating layer. The first and second isolation patterns IS1 and IS2 may further include common source plugs (not illustrated) that are connected to the common source region of the substrate 10. In an embodiment, in each of the first and second isolation patterns IS1 and IS2, the common source plug may be configured in a plate shape that extends in the first horizontal direction HD1, and the insulating layer may be configured in a spacer shape between the electrode structure ST, the first, second, third and fourth drain select lines DSL1, DSL2, DSL3 and DSL4 and the dummy patterns DP and the common source plug. In another embodiment, in each of the first and second isolation patterns IS1 and IS2, the insulating layer may be configured in a plate shape that extends in the first horizontal direction HD1, and the common source plug may be configured in a plug shape that penetrates the insulating layer, to be locally connected to the common source region of the substrate 10.

A first insulating layer 90 may be disposed on or over the first, second, third and fourth drain select lines DSL1, DSL2, DSL3 and DSL4 and the dummy patterns DP to cover the first, second, third and fourth drain select lines DSL1, DSL2, DSL3 and DSL4 and the dummy patterns DP. The first and second isolation patterns IS1 and IS2 may penetrate the first insulating layer 90 in a vertical direction VD.

A first isolation insulating pattern 41 is disposed between the first drain select lines DSL1 and the second drain select lines DSL2. The first isolation insulating pattern 41 may insulate the first drain select lines DSL1 and the second drain select lines DSL2.

A second isolation insulating pattern 42 is disposed between the second drain select lines DSL2 and the third drain select lines DSL3. The second isolation insulating pattern 42 may insulate the second drain select lines DSL2 and the third drain select lines DSL3.

A third isolation insulating pattern 43 is disposed between the third drain select lines DSL3 and the fourth drain select lines DSL4. The third isolation insulating pattern 43 may insulate the third drain select lines DSL3 and the fourth drain select lines DSL4.

A fourth isolation insulating pattern 44 is disposed between the first drain select lines DSL1 and the dummy patterns DP. The fourth isolation insulating pattern 44 may insulate the first drain select lines DSL1 and the dummy patterns DP.

The first, second, third and fourth isolation insulating patterns 41, 42, 43 and 44 may extend in the vertical direction VD and penetrate the dummy word lines DWLa, DWLb, DWLc and DWLd. The dummy word lines DWLa, DWLb, DWLc and DWLd may be divided by the first, second, third and fourth isolation insulating patterns 41, 42, 43 and 44. The first, second, third and fourth isolation insulating patterns 41, 42, 43 and 44 may penetrate the first insulating layer 90 in the vertical direction VD.

Referring to FIG. 9, each of the first, second, third and fourth drain select lines DSL1, DSL2, DSL3 and DSL4 includes an electrode section ES, a first pad section PS1 and a second pad section PS2.

The electrode sections ES of the first, second, third and fourth drain select lines DSL1, DSL2, DSL3 and DSL4 are disposed in the cell region CAR. The first pad sections PS1 of the first, second, third and fourth drain select lines DSL1, DSL2, DSL3 and DSL4 are disposed in the first connection region CNR1. The second pad sections PS2 of the first, second, third and fourth drain select lines DSL1, DSL2, DSL3 and DSL4 are disposed in the second connection region CNR2.

In the cell region CAR, the electrode section ES of the first drain select line DSL1, the electrode section ES of the second drain select line DSL2, the electrode section ES of the third drain select line DSL3 and the electrode section ES of the fourth drain select line DSL4 may be disposed in a line along the second horizontal direction HD2. The electrode section ES of the first drain select line DSL1, the electrode section ES of the second drain select line DSL2, the electrode section ES of the third drain select line DSL3 and the electrode section ES of the fourth drain select line DSL4 may have the same dimension in the second horizontal direction HD2.

In the first connection region CNR1, the first pad section PS1 of the first drain select line DSL1, the first pad section PS1 of the second drain select line DSL2, the first pad section PS1 of the third drain select line DSL3 and the first pad section PS1 of the fourth drain select line DSL4 may be disposed in a line along the second horizontal direction HD2.

In each of the first, second, third and fourth drain select lines DSL1, DSL2, DSL3 and DSL4, the dimension of the first pad section PS1 in the second horizontal direction HD2 may be the same as the dimension of the electrode section ES in the second horizontal direction HD2. For example, in the fourth drain select line DSL4, the dimension of the electrode section ES in the second horizontal direction HD2 and the dimension of the first pad section PS1 in the second horizontal direction HD2 may be the same dimension Wa.

In the second connection region CNR2, the second pad section PS2 of the first drain select line DSL1, the second pad section PS2 of the second drain select line DSL2, the second pad section PS2 of the third drain select line DSL3 and the second pad section PS2 of the fourth drain select line DSL4 may be disposed in a line along the first horizontal direction HD1.

In each of the first, second, third and fourth drain select lines DSL1, DSL2, DSL3 and DSL4, the maximum dimension of the second pad section PS2 in the second horizontal direction HD2 may be larger than the dimension of the first pad section PS1 in the second horizontal direction HD2. For example, in the fourth drain select line DSL4, the dimension of the first pad section PS1 in the second horizontal direction HD2 may be Wa, and the maximum dimension of the second pad section PS2 in the second horizontal direction HD2 may be Wb4, which is larger than Wa.

The maximum dimension of the second pad section PS2 of the first drain select line DSL1 in the second horizontal direction HD2 may be larger than the maximum dimension of the second pad section PS2 of the second drain select line DSL2 in the second horizontal direction HD2; the maximum dimension of the second pad section PS2 of the second drain select line DSL2 in the second horizontal direction HD2 may be larger than the maximum dimension of the second pad section PS2 of the third drain select line DSL3 in the second horizontal direction HD2; and the maximum dimension of the second pad section PS2 of the third drain select line DSL3 in the second horizontal direction HD2 may be larger than the maximum dimension of the second pad section PS2 of the fourth drain select line DSL4 in the second horizontal direction HD2. For example, when the maximum dimension of the second pad section PS2 of the first drain select line DSL1 in the second horizontal direction HD2 is Wb1, the maximum dimension of the second pad section PS2 of the second drain select line DSL2 in the second horizontal direction HD2 is Wb2, the maximum dimension of the second pad section PS2 of the third drain select line DSL3 in the second horizontal direction HD2 is Wb3 and the maximum dimension of the second pad section PS2 of the fourth drain select line DSL4 in the second horizontal direction HD2 is Wb4, the relationship Wb1>Wb2>Wb3>Wb4 may be satisfied.

Referring again to FIG. 1 to FIG. 6, drain contacts 51a, 51b, 51c, 52a, 52b, 52c, 53a, 53b, 53c, 54a, 54b and 54c are disposed in the first connection region CNR1. The drain contacts 51a, 51b, 51c, 52a, 52b, 52c, 53a, 53b, 53c, 54a, 54b and 54c include first drain contacts 51a, 51b and 51c, second drain contacts 52a, 52b and 52c, third drain contacts 53a, 53b and 53c, and fourth drain contacts 54a, 54b and 54c.

Referring again to FIG. 1 to FIG. 3, the first drain contacts 51a, 51b and 51c extend in the vertical direction VD and are connected to the first drain select lines DSL1, respectively. Specifically, the first drain contact 51a is connected to the first lower drain select line DSL1a, the first drain contact 51b is connected to the first intermediate drain select line DSL1b, and the first drain contact 51c is connected to the first upper drain select line DSL1c. The bottom surfaces of the first drain contacts 51a, 51b and 51c may be disposed at different heights as measured from the top surface of the substrate 10. Specifically, the bottom surface of the first drain contact 51a may contact the pad section of the first lower drain select line DSL1a, the bottom surface of the first drain contact 51b may contact the pad section of the first intermediate drain select line DSL1b, and the bottom surface of the first drain contact 51c may contact the pad section of the first upper drain select line DSL1c.

First insulating spacers S1 may be defined and disposed on the side surfaces of the first drain contacts 51a, 51b and 51c to surround the side surfaces of the first drain contacts 51a, 51b and 51c, respectively. The first drain contacts 51a, 51b and 51c may be disposed in a line along the first horizontal direction HD1.

Referring again to FIG. 1, FIG. 2 and FIG. 4, the second drain contacts 52a, 52b and 52c extend in the vertical direction VD and are connected to the second drain select lines DSL2, respectively. Specifically, the second drain contact 52a is connected to the second lower drain select line DSL2a, the second drain contact 52b is connected to the second intermediate drain select line DSL2b, and the second drain contact 52c is connected to the second upper drain select line DSL2c. The bottom surfaces of the second drain contacts 52a, 52b and 52c may be disposed at different heights from the top surface of the substrate 10. Specifically, the bottom surface of the second drain contact 52a may contact the pad section of the second lower drain select line DSL2a, the bottom surface of the second drain contact 52b may contact the pad section of the second intermediate drain select line DSL2b, and the bottom surface of the second drain contact 52c may contact the pad section of the second upper drain select line DSL2c.

Second insulating spacers S2 may be defined and disposed on the side surfaces of the second drain contacts 52a, 52b and 52c to surround the side surfaces of the second drain contacts 52a, 52b and 52c, respectively. The second drain contacts 52a, 52b and 52c may be disposed in a line along the first horizontal direction HD1.

Referring again to FIG. 1, FIG. 2 and FIG. 5, the third drain contacts 53a, 53b and 53c extend in the vertical direction VD and are connected to the third drain select lines DSL3, respectively. Specifically, the third drain contact 53a is connected to the third lower drain select line DSL3a, the third drain contact 53b is connected to the third intermediate drain select line DSL3b, and the third drain contact 53c is connected to the third upper drain select line DSL3c. The bottom surfaces of the third drain contacts 53a, 53b and 53c may be disposed at different heights from the top surface of the substrate 10. Specifically, the bottom surface of the third drain contact 53a may contact the pad section of the third lower drain select line DSL3a, the bottom surface of the third drain contact 53b may contact the pad section of the third intermediate drain select line DSL3b, and the bottom surface of the third drain contact 53c may contact the pad section of the third upper drain select line DSL3c.

Third insulating spacers S3 may be defined and disposed on the side surfaces of the third drain contacts 53a, 53b and 53c to surround the side surfaces of the third drain contacts 53a, 53b and 53c, respectively. The third drain contacts 53a, 53b and 53c may be disposed in a line along the first horizontal direction HD1.

Referring again to FIG. 1, FIG. 2 and FIG. 6, the fourth drain contacts 54a, 54b and 54c extend in the vertical direction VD and are connected to the fourth drain select lines DSL4, respectively. Specifically, the fourth drain contact 54a is connected to the fourth lower drain select line DSL4a, the fourth drain contact 54b is connected to the fourth intermediate drain select line DSL4b, and the fourth drain contact 54c is connected to the fourth upper drain select line DSL4c. The bottom surfaces of the fourth drain contacts 54a, 54b and 54c may be disposed at different heights from the top surface of the substrate 10. Specifically, the bottom surface of the fourth drain contact 54a may contact the pad section of the fourth lower drain select line DSL4a, the bottom surface of the fourth drain contact 54b may contact the pad section of the fourth intermediate drain select line DSL4b, and the bottom surface of the fourth drain contact 54c may contact the pad section of the fourth upper drain select line DSL4c.

Fourth insulating spacers S4 may be defined and disposed on the side surfaces of the fourth drain contacts 54a, 54b and 54c to surround the side surfaces of the fourth drain contacts 54a, 54b and 54c, respectively. The fourth drain contacts 54a, 54b and 54c may be disposed in a line along the first horizontal direction HD1.

Referring again to FIG. 1 to FIG. 6, a second insulating layer 92 may be disposed on the first insulating layer 90, and a first wiring layer may be formed on the second insulating layer 92. The first wiring layer includes a plurality of drain select line connection wirings 71, 72, 73 and 74. The drain select line connection wirings 71, 72, 73 and 74 may include a first drain select line connection wiring 71, a second drain select line connection wiring 72, a third drain select line connection wiring 73, and a fourth drain select line connection wiring 74.

The first, second, third and fourth drain select line connection wirings 71, 72, 73 and 74 may extend across the second connection region CNR2 to the first connection region CNR1 in the first horizontal direction HD1.

Under the first drain select line connection wiring 71, first vias V1 may penetrate the second insulating layer 92 in the vertical direction VD and connect the first drain select line connection wiring 71 to the first drain contacts 51a, 51b and 51c, respectively. The first lower drain select line DSL1a, the first intermediate drain select line DSL1b and the first upper drain select line DSL1c may be connected in common to the first drain select line connection wiring 71 through the first drain contacts 51a, 51b and 51c and the first vias V1.

Under the second drain select line connection wiring 72, second vias V2 may penetrate the second insulating layer 92 in the vertical direction VD and connect the second drain select line connection wiring 72 to the second drain contacts 52a, 52b and 52c, respectively. The second lower drain select line DSL2a, the second intermediate drain select line DSL2b and the second upper drain select line DSL2c may be connected in common to the second drain select line connection wiring 72 through the second drain contacts 52a, 52b and 52c and the second vias V2.

Under the third drain select line connection wiring 73, third vias V3 may penetrate the second insulating layer 92 in the vertical direction VD and connect the third drain select line connection wiring 73 to the third drain contacts 53a, 53b and 53c, respectively. The third lower drain select line DSL3a, the third intermediate drain select line DSL3b and the third upper drain select line DSL3c may be connected in common to the third drain select line connection wiring 73 through the third drain contacts 53a, 53b and 53c and the third vias V3.

Under the fourth drain select line connection wiring 74, fourth vias V4 may penetrate the second insulating layer 92 in the vertical direction VD and connect the fourth drain select line connection wiring 74 to the fourth drain contacts 54a, 54b and 54c, respectively. The fourth lower drain select line DSL4a, the fourth intermediate drain select line DSL4b and the fourth upper drain select line DSL4c may be connected in common to the fourth drain select line connection wiring 74 through the fourth drain contacts 54a, 54b and 54c and the fourth vias V4.

Referring again to FIG. 1, FIG. 7, FIG. 8 and FIG. 9, dummy contacts 61a to 61d, 62a to 62d, 63a to 63d and 64a to 64d are disposed in the second connection region CNR2. For example, in FIG. 1, the dummy contacts 61a to 61d, 62a to 62d, 63a to 63d and 64a to 64d are disposed in two rows arranged in the second horizontal direction HD2.

The dummy contacts 61a to 61d, 62a to 62d, 63a to 63d and 64a to 64d include first dummy contacts 61a to 61d, second dummy contacts 62a to 62d, third dummy contacts 63a to 63d, and fourth dummy contacts 64a to 64d.

The first dummy contacts 61a to 61d may extend in the vertical direction VD through the first drain select lines DSL1 and may be connected to the first, second, third and fourth dummy word lines DWLa, DWLb, DWLc and DWLd, respectively. The first dummy contacts 61a to 61d may penetrate the second pad sections PS2 of the first drain select lines DSL1 in the vertical direction VD. Fifth insulating spacers S5 may be defined and disposed on the side surfaces of the first dummy contacts 61a to 61d to surround the side surfaces of the first dummy contacts 61a to 61d.

The second dummy contacts 62a to 62d may extend in the vertical direction VD through the second drain select lines DSL2 and may be connected to the first, second, third and fourth dummy word lines DWLa, DWLb, DWLc and DWLd, respectively. The second dummy contacts 62a to 62d may penetrate the second pad sections PS2 of the second drain select lines DSL2 in the vertical direction VD. Sixth insulating spacers S6 may be defined and disposed on the side surfaces of the second dummy contacts 62a to 62d to surround the side surfaces of the second dummy contacts 62a to 62d.

The third dummy contacts 63a to 63d may extend in the vertical direction VD through the third drain select lines DSL3 and may be connected to the first, second, third and fourth dummy word lines DWLa, DWLb, DWLc and DWLd, respectively. The third dummy contacts 63a to 63d may penetrate the second pad sections PS2 of the third drain select lines DSL3 in the vertical direction VD. Seventh insulating spacers S7 may be defined and disposed on the side surfaces of the third dummy contacts 63a to 63d to surround the side surfaces of the third dummy contacts 63a to 63d.

The fourth dummy contacts 64a to 64d may extend in the vertical direction VD through the fourth drain select lines DSL4 and may be connected to the first, second, third and fourth dummy word lines DWLa, DWLb, DWLc and DWLd, respectively. The fourth dummy contacts 64a to 64d may penetrate the second pad sections PS2 of the fourth drain select lines DSL4 in the vertical direction VD. Eighth insulating spacers S8 may be defined and disposed on the side surfaces of the fourth dummy contacts 64a to 64d to surround the side surfaces of the fourth dummy contacts 64a to 64d.

One of the first dummy contacts 61a to 61d, one of the second dummy contacts 62a to 62d, one of the third dummy contacts 63a to 63d and one of the fourth dummy contacts 64a to 64d may be connected in common to each of the first, second, third and fourth dummy word lines DWLa, DWLb, DWLc and DWLd. Specifically, the first dummy contact 61a, the second dummy contact 62a, the third dummy contact 63a and the fourth dummy contact 64a may be connected in common to the first dummy word line DWLa. The first dummy contact 61b, the second dummy contact 62b, the third dummy contact 63b and the fourth dummy contact 64b may be connected in common to the second dummy word line DWLb. The first dummy contact 61c, the second dummy contact 62c, the third dummy contact 63c and the fourth dummy contact 64c may be connected in common to the third dummy word line DWLc. The first dummy contact 61d, the second dummy contact 62d, the third dummy contact 63d and the fourth dummy contact 64d may be connected in common to the fourth dummy word line DWLd.

The first wiring layer includes dummy word line connection wirings 81, 82, 83 and 84. The dummy word line connection wirings 81, 82, 83 and 84 are disposed on the second insulating layer 92. The dummy word line connection wirings 81, 82, 83 and 84 may include a first dummy word line connection wiring 81, a second dummy word line connection wiring 82, a third dummy word line connection wiring 83, and a fourth dummy word line connection wiring 84.

Fifth vias V5 that penetrate the second insulating layer 92 in the vertical direction VD may be disposed under the first dummy word line connection wiring 81. The first dummy word line connection wiring 81 may be connected to the first, second, third and fourth dummy contacts 61a, 62a, 63a and 64a through the fifth vias V5.

The first dummy word line DWLa may be divided into a plurality of sections by the first, second, third and fourth isolation insulating patterns 41, 42, 43 and 44. The first dummy word line connection wiring 81 may be connected in common to the divided sections of the first dummy word line DWLa through the fifth vias V5 and the first, second, third and fourth dummy contacts 61a, 62a, 63a and 64a. Accordingly, the divided sections of the first dummy word line DWLa may have an equipotential state.

Sixth vias V6 that penetrate the second insulating layer 92 in the vertical direction VD may be disposed under the second dummy word line connection wiring 82. The second dummy word line connection wiring 82 may be connected to the first, second, third and fourth dummy contacts 61b, 62b, 63b and 64b through the sixth vias V6.

The second dummy word line DWLb may be divided into a plurality of sections by the first, second, third and fourth isolation insulating patterns 41, 42, 43 and 44. The second dummy word line connection wiring 82 may be connected in common to the divided sections of the second dummy word line DWLb through the sixth vias V6 and the first, second, third and fourth dummy contacts 61b, 62b, 63b and 64b. Accordingly, the divided sections of the second dummy word line DWLb may have an equipotential state.

Seventh vias V7 that penetrate the second insulating layer 92 in the vertical direction VD may be disposed under the third dummy word line connection wiring 83. The third dummy word line connection wiring 83 may be connected to the first, second, third and fourth dummy contacts 61c, 62c, 63c and 64c through the seventh vias V7.

The third dummy word line DWLc may be divided into a plurality of sections by the first, second, third and fourth isolation insulating patterns 41, 42, 43 and 44. The third dummy word line connection wiring 83 may be connected in common to the divided sections of the third dummy word line DWLc through the seventh vias V7 and the first, second, third and fourth dummy contacts 61c, 62c, 63c and 64c. Accordingly, the divided sections of the third dummy word line DWLc may have an equipotential state.

Eighth vias V8 that penetrate the second insulating layer 92 in the vertical direction VD may be disposed under the fourth dummy word line connection wiring 84. The fourth dummy word line connection wiring 84 may be connected to the first, second, third and fourth dummy contacts 61d, 62d, 63d and 64d through the eighth vias V8.

The fourth dummy word line DWLd may be divided into a plurality of sections by the first, second, third and fourth isolation insulating patterns 41, 42, 43 and 44. The fourth dummy word line connection wiring 84 may be connected in common to the divided sections of the fourth dummy word line DWLd through the eighth vias V8 and the first, second, third and fourth dummy contacts 61d, 62d, 63d and 64d. Accordingly, the divided sections of the fourth dummy word line DWLd may have an equipotential state.

Referring to FIG. 7 and FIG. 10, dummy contacts that are connected in common to one of the first, second, third and fourth dummy word lines DWLa, DWLb, DWLc and DWLd may be disposed in the same row. In an embodiment, the first, second, third and fourth dummy contacts 61a, 62a, 63a and 64a connected in common to the first dummy word line DWLa and the first, second, third and fourth dummy contacts 61b, 62b, 63b and 64b connected in common to the second dummy word line DWLb may be disposed in a line along the first horizontal direction HD1 to form a first row R<1>, and the first, second, third and fourth dummy contacts 61c, 62c, 63c and 64c connected in common to the third dummy word line DWLc and the first, second, third and fourth dummy contacts 61d, 62d, 63d and 64d connected in common to the fourth dummy word line DWLd may be disposed in a line along the first horizontal direction HD1 to form a second row R<2>.

The number of rows of dummy contacts may be smaller than the number of drain select lines included in each drain select line layer. While the figures in the present disclosure illustrate four drain select lines included in each drain select line layer and two rows of dummy contacts, other embodiments may have different numbers of drain select lines and dummy contacts.

The first dummy word line connection wiring 81 may include a main line 81a that extends in the first horizontal direction HD1 and branch lines 81b that are branched from the main line 81a. The second dummy word line connection wiring 82 may include a main line 82a that extends in the first horizontal direction HD1 and branch lines 82b that are branched from the main line 82a.

The main line 81a of the first dummy word line connection wiring 81 and the main line 82a of the second dummy word line connection wiring 82 may be parallel in the first horizontal direction HD1 and disposed on both sides, respectively, of the first row R<1>.

The branch lines 81b of the first dummy word line connection wiring 81 may be branched from the main line 81a of the first dummy word line connection wiring 81 in the vicinity of the first, second, third and fourth dummy contacts 61a, 62a, 63a and 64a and may be connected to the first, second, third and fourth dummy contacts 61a, 62a, 63a and 64a, respectively. The branch lines 81b of the first dummy word line connection wiring 81 may have a shorter length that connects the main line 81a of the first dummy word line connection wiring 81 and the first, second, third and fourth dummy contacts 61a, 62a, 63a and 64a.

The branch lines 82b of the second dummy word line connection wiring 82 may be branched from the main line 82a of the second dummy word line connection wiring 82 in the vicinity of the first, second, third and fourth dummy contacts 61b, 62b, 63b and 64b and may be connected to the first, second, third and fourth dummy contacts 61b, 62b, 63b and 64b, respectively. The branch lines 82b of the second dummy word line connection wiring 82 may have a shorter length that connects the main line 82a of the second dummy word line connection wiring 82 and the first, second, third and fourth dummy contacts 61b, 62b, 63b and 64b.

The third dummy word line connection wiring 83 may include a main line 83a that extends in the first horizontal direction HD1 and branch lines 83b that are branched from the main line 83a. The fourth dummy word line connection wiring 84 may include a main line 84a that extends in the first horizontal direction HD1 and branch lines 84b that are branched from the main line 84a.

The main line 83a of the third dummy word line connection wiring 83 and the main line 84a of the fourth dummy word line connection wiring 84 may be parallel in the first horizontal direction HD1 and disposed on both sides, respectively, of the second row R<2>.

The branch lines 83b of the third dummy word line connection wiring 83 may be branched from the main line 83a of the third dummy word line connection wiring 83 in the vicinity of the first, second, third and fourth dummy contacts 61c, 62c, 63c and 64c and may be connect to the first, second, third and fourth dummy contacts 61c, 62c, 63c and 64c, respectively. The branch lines 83b of the third dummy word line connection wiring 83 may have a shorter length that connects the main line 83a of the third dummy word line connection wiring 83 and the first, second, third and fourth dummy contacts 61c, 62c, 63c and 64c.

The branch lines 84b of the fourth dummy word line connection wiring 84 may be branched from the main line 84a of the fourth dummy word line connection wiring 84 in the vicinity of the first, second, third and fourth dummy contacts 61d, 62d, 63d and 64d and may be connected to the first, second, third and fourth dummy contacts 61d, 62d, 63d and 64d. The branch lines 84b of the fourth dummy word line connection wiring 84 may have a shorter length that connects the main line 84a of the fourth dummy word line connection wiring 84 and the first, second, third and fourth dummy contacts 61d, 62d, 63d and 64d.

Referring again to FIG. 1 and FIG. 3, a plurality of cell plugs CP may be disposed in the cell region CAR. The cell plugs CP may extend vertically into the substrate 10 through the first insulating layer 90, the drain select lines DSL1, DSL2, DSL3 or DSL4 and the electrode structure ST. Each cell plug CP may include a channel layer CL and a memory layer ML. The channel layer CL may include a semiconductor material. For example, the channel layer CL may include polysilicon. The memory layer ML may have a straw or cylinder shell shape that surrounds an outer wall of the channel layer CL. The memory layer ML may include a tunnel insulating layer that surrounds or covers the channel layer CL, a data storage layer that surrounds or covers the tunnel insulating layer, and a blocking layer that surrounds or covers the data storage layer.

A source select transistor may be configured in an area where the source select line SSL surrounds the cell plug CP. Memory cells may be configured in areas where the word lines WL surround the cell plug CP. Dummy memory cells may be configured in areas where the dummy word lines DWLa, DWLb, DWLc and DWLd surround the cell plug CP. Drain select transistors may be configured in areas where the drain select lines DSL1, DSL2, DSL3 and DSL4 surround the cell plug CP.

The first wiring layer includes bit lines BL. The bit lines BL are disposed on the second insulating layer 92. A bit line contact BLC that penetrates the second insulating layer 92 in the vertical direction VD is disposed under the bit line BL. The cell plug CP is connected to the bit line BL through the bit line contact BLC.

The first, second, third and fourth isolation insulating patterns 41, 42, 43 and 44 may be formed by forming slits through an etching process and filling the slits with an insulating material. In order to prevent drain select lines, which should be insulated from each other, from being shorted, the target depth of the etching process for forming the slits should be increased to secure process margins. When the target depth of the etching process for isolation insulating patterns is increased, the number of dummy word lines to be divided by the first, second, third and fourth isolation insulating patterns 41, 42, 43 and 44, and the number of dummy word line connection wirings that connect divided sections of the dummy word lines, need to increase. When the number of dummy word line connection wirings increases, wiring bottlenecks may occur and it may be difficult to dispose drain select line connection wirings. By reducing wiring pitch or additionally forming a wiring layer, wiring bottlenecks may be resolved. However, when wiring pitch is reduced, wiring resistance may increase and lead to deterioration in signal characteristics, and when additional wiring layers are formed, the number of process steps may increase and manufacturing costs may increase.

According to embodiments of the present disclosure, the dummy contacts 61a to 61d, 62a to 62d, 63a to 63d and 64a to 64d are arranged in a plurality of rows spaced apart in the second horizontal direction HD2. By disposing dummy contacts connected to the same dummy word line in a single row, the main lines 81a, 82a, 83a and 84a of the dummy word line connection wirings 81, 82, 83 and 84 can also extend in the first horizontal direction HD1 in parallel to the rows of dummy contacts. Accordingly, because, in the second connection region CNR2, the main lines 81a, 82a, 83a and 84a of the dummy word line connection wirings 81, 82, 83 and 84 are disposed parallel to the drain select line connection wirings 71, 72, 73 and 74, wiring bottlenecks can be avoided without reducing wiring pitch or forming an additional wiring layer. In addition, because wiring bottlenecks are addressed with disclosed arrangements of structures, the number of dummy word line connection wirings can increase, and the number of dummy word lines that are divided by the first, second, third and fourth isolation insulating patterns 41, 42, 43 and 44 may increase. Therefore, an etching target depth for isolation insulating patterns may be increased in etching processes forming slits for the patterns, thereby improving etching margins.

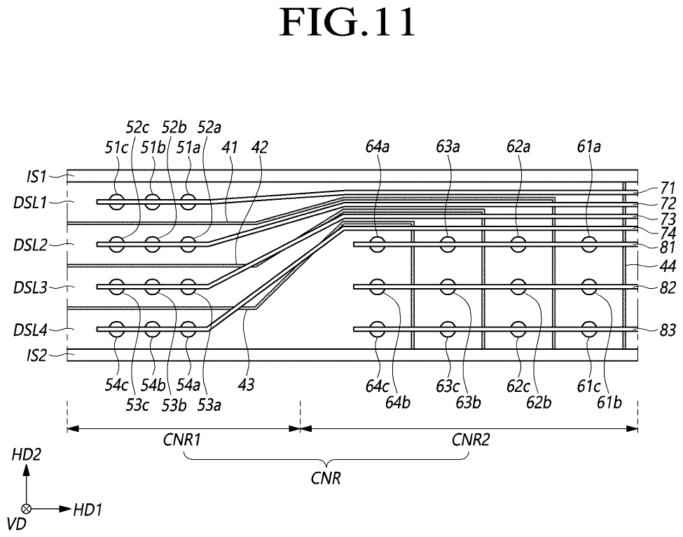

In embodiments of the present disclosure described above with reference to FIG. 1 to FIG. 10, dummy contacts that are disposed in one row are connected to two dummy word lines, but embodiments of the present disclosure are not limited thereto. As will be described below with reference to FIG. 11 to FIG. 14, dummy contacts connected to different dummy word lines may be disposed in different rows.

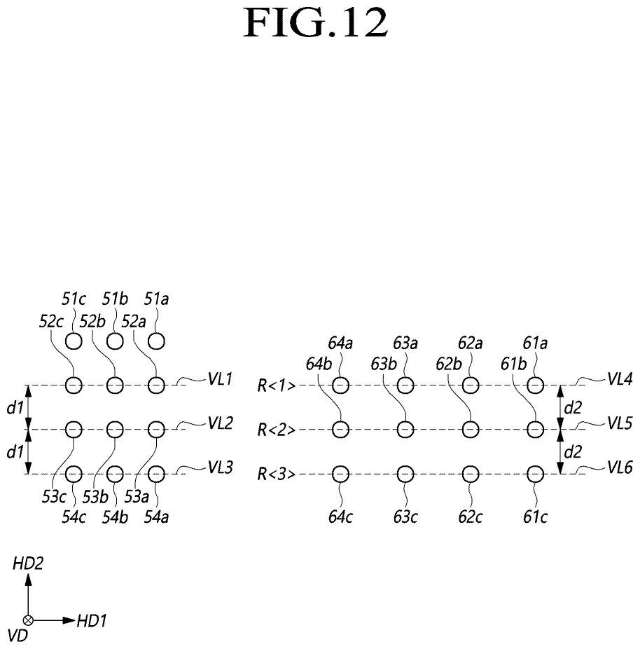

FIG. 11 is a plan view of a memory device according to embodiments of the present disclosure, and FIG. 12 is a plan view illustrating drain contacts and dummy contacts of FIG. 11.

Referring to FIG. 11 and FIG. 12, dummy contacts connected to the same dummy word line are disposed in the same row along a first horizontal direction HD1. Dummy contacts connected to a different dummy word line are disposed in a different row that is spaced apart in a second horizontal direction SD perpendicular to the first horizontal direction FD.

Specifically, first, second, third and fourth dummy contacts 61a, 62a, 63a and 64a, which are connected in common to a first dummy word line, may be disposed in a line along the first horizontal direction HD1 to form a first row R<1>. First, second, third and fourth dummy contacts 61b, 62b, 63b and 64b, which are connected in common to a second dummy word line, may be disposed in a line along the first horizontal direction HD1 to form a second row R<2>. First, second, third and fourth dummy contacts 61c, 62c, 63c and 64c, which are connected in common to a third dummy word line, may be disposed in a line along the first horizontal direction HD1 to form a third row R<3>.

A first dummy word line connection wiring 81 is connected to the first, second, third and fourth dummy contacts 61a, 62a, 63a and 64a connected to the first dummy word line. A second dummy word line connection wiring 82 is connected to the first, second, third and fourth dummy contacts 61b, 62b, 63b and 64b connected to the second dummy word line. A third dummy word line connection wiring 83 is connected to the first, second, third and fourth dummy contacts 61c, 62c, 63c and 64c connected to the third dummy word line. The first, second and third dummy word line connection wirings 81, 82 and 83 may be parallel to each other and each may extend in the first horizontal direction HD1. In a second connection region CNR2, the first, second and third dummy word line connection wirings 81, 82 and 83 may be disposed to be parallel to drain select line connection wirings 71, 72, 73 and 74, which also extend in the first horizontal direction HD1.

Among the dummy contacts, dummy contacts that penetrate the same drain select line may be arranged in a line along the second horizontal direction HD2. Specifically, the first dummy contacts 61a, 61b and 61c, which penetrate a first drain select line DSL1, may be disposed in a line along the second horizontal direction HD2. Arrangements similar to that of the first dummy contacts 61a, 61b and 61c also apply similarly to the second dummy contacts 62a, 62b and 62c, the third dummy contacts 63a, 63b and 63c and the fourth dummy contacts 64a, 64b and 64c.

In embodiments of the present disclosure, the first row R<1> is disposed with second drain contacts 52a, 52b and 52c on the same straight line along the first horizontal direction HD1, the second row R<2> is disposed with third drain contacts 53a, 53b and 53c on the same straight line along the first horizontal direction HD1, and the third row R<3> is disposed with fourth drain contacts 54a, 54b and 54c on the same straight line along the first horizontal direction HD1.

A virtual first line VL1 is defined by crossing the centers of the second drain contacts 52a, 52b and 52c in the first horizontal direction HD1, a virtual second line VL2 is defined by crossing the centers of the third drain contacts 53a, 53b and 53c in the first horizontal direction HD1 and a virtual third line VL3 is defined by crossing the centers of the fourth drain contacts 54a, 54b and 54c in the first horizontal direction HD1. The distance between the virtual first line VL1 and the virtual second line VL2, and the distance between the virtual second line VL2 and the virtual third line VL3, may each be a dimension d1, which may be defined as the pitch of drain contacts in the second horizontal direction HD2.

A virtual fourth line VL4 is defined by crossing the centers of the dummy contacts 61a, 62a, 63a and 64a of the first row R<1> in the first horizontal direction HD1, a virtual fifth line VL5 is defined by crossing the centers of the dummy contacts 61b, 62b, 63b and 64b of the second row R<2> in the first horizontal direction HD1 and a virtual sixth line VL6 is defined by crossing the centers of the dummy contacts 61c, 62c, 63c and 64c of the third row R<3> in the first horizontal direction HD1. The distance between the virtual fourth line VL4 and the virtual fifth line VL5, and the distance between the virtual fifth line VL5 and the virtual sixth line VL6, may each be a dimension d2, which may be defined as the pitch of dummy contacts in the second horizontal direction HD2. In embodiments, d2 may be the same as d1.

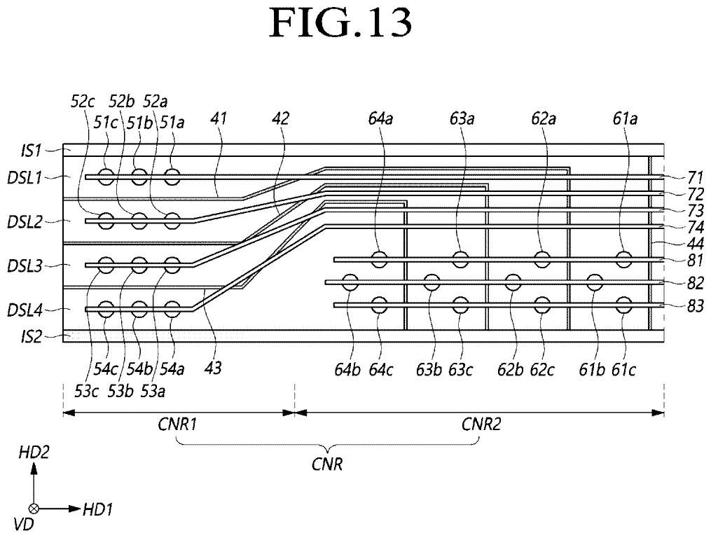

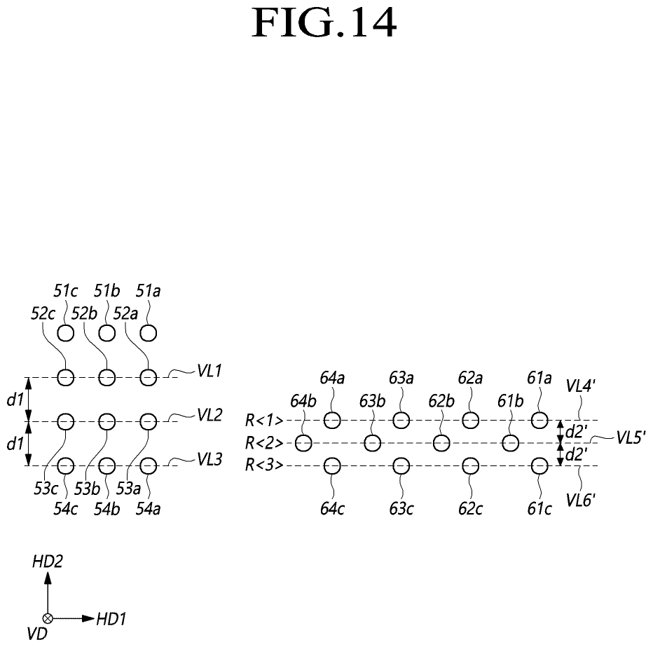

FIG. 13 is a plan view of a memory device according to embodiments of the present disclosure, and FIG. 14 is a plan view illustrating drain contacts and dummy contacts of FIG. 13.

Referring to FIG. 13 and FIG. 14, dummy contacts that are disposed in neighboring rows may be offset from each other in the first horizontal direction HD1. For example, dummy contacts 61a, 62a, 63a and 64a of a first row R<1> and dummy contacts 61b, 62b, 63b and 64b of a second row R<2> may be offset from each other in the first horizontal direction HD1, and the dummy contacts 61b, 62b, 63b and 64b of the second row R<2> and dummy contacts 61c, 62c, 63c and 64c of a third row R<3> may be offset from each other in the first horizontal direction HD1.

The dummy contacts 61a, 62a, 63a and 64a of the first row R<1> and the dummy contacts 61b, 62b, 63b and 64b of the second row R<2> may be arranged, respectively, in a diagonal direction that intersects the first horizontal direction HD1 and the second horizontal direction HD2. The dummy contacts 61b, 62b, 63b and 64b of the second row R<2> and the dummy contacts 61c, 62c, 63c and 64c of the third row R<3> may be arranged, respectively, in a diagonal direction that intersects the first horizontal direction HD1 and the second horizontal direction HD2. A virtual line connecting the centers of dummy contacts 61a, 61b and 61c may form a chevron.

A virtual first line VL1 that crosses the centers of second drain contacts 52a, 52b and 52c in the first horizontal direction HD1, a virtual second line VL2 that crosses the centers of third drain contacts 53a, 53b and 53c in the first horizontal direction HD1 and a virtual third line VL3 that crosses the centers of fourth drain contacts 54a, 54b and 54c in the first horizontal direction HD1 may be defined as parallel to each other while extending in the first horizontal direction HD1. Each of the distance between the virtual first line VL1 and the virtual second line VL2, and the distance between the virtual second line VL2 and the virtual third line VL3, may have a dimension of d1, which may be defined as the pitch of drain contacts in the second horizontal direction HD2.

A virtual fourth line VL4′ that crosses the centers of the dummy contacts 61a, 62a, 63a and 64a of the first row R<1> in the first horizontal direction HD1, a virtual fifth line VL5′ that crosses the centers of the dummy contacts 61b, 62b, 63b and 64b of the second row R<2> in the first horizontal direction HD1 and a virtual sixth line VL6′ that crosses the centers of the dummy contacts 61c, 62c, 63c and 64c of the third row R<3> in the first horizontal direction HD1 may be defined as parallel to each other while extending in the first horizontal direction HD1. The distance between the virtual fourth line VL4′ and the virtual fifth line VL5′ and the distance between the virtual fifth line VL5′ and the virtual sixth line VL6′ may have a dimension of d2′, which may be defined as the pitch of dummy contacts in the second horizontal direction HD2. In embodiments of the disclosure, d2′ is smaller than d1.

Because dummy contacts that are disposed in neighboring rows face each other in a diagonal direction, the pitch of the dummy contacts in the second horizontal direction HD2 may be reduced without narrowing the distance between the dummy contacts. Accordingly, because it is possible to reduce the pitch of dummy word line connection wirings, the area available for the disposition of drain select line connection wirings may be increased or established with more secure margins.

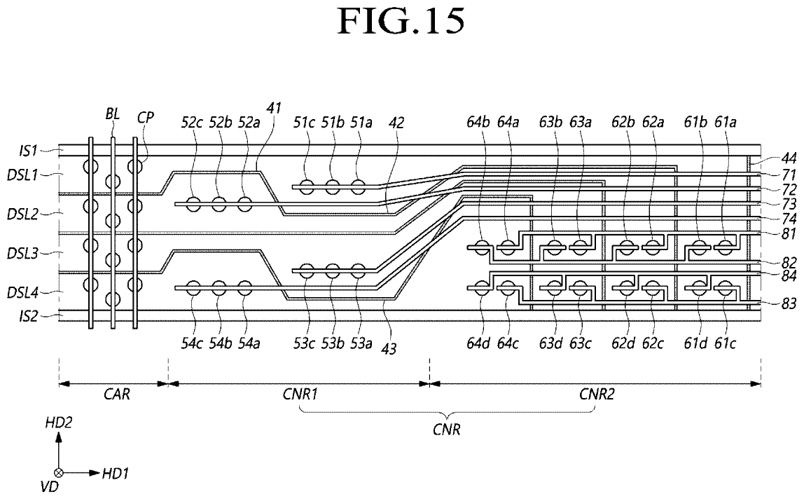

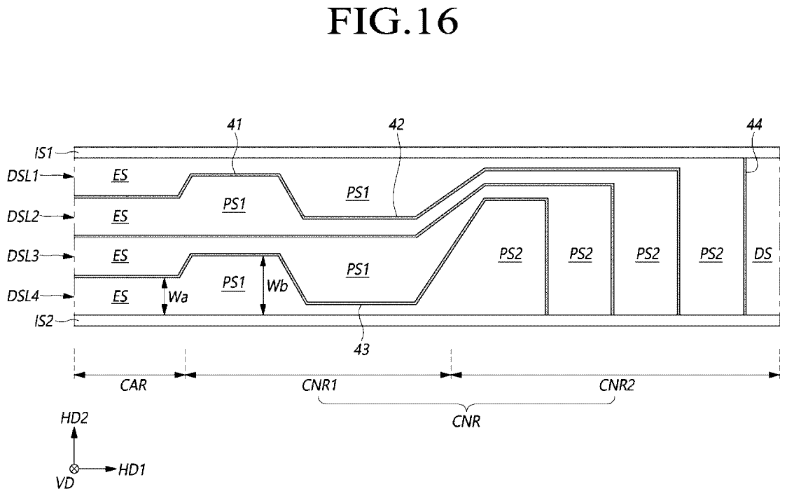

FIG. 15 is a plan view of a memory device according to embodiments of the present disclosure, and FIG. 16 is a plan view illustrating drain select lines and isolation insulating patterns of FIG. 15. Descriptions of the same elements described above will be omitted for clarity.

Referring to FIG. 15 and FIG. 16, a first pad section PS1 of a first drain select line DSL1 and a first pad section PS1 of a second drain select line DSL2 may be disposed in a line along the first horizontal direction HD1, and a first pad section PS1 of a third drain select line DSL3 and a first pad section PS1 of a fourth drain select line DSL4 may be disposed in a line along the first horizontal direction HD1.

In each of the first, second, third and fourth drain select lines DSL1, DSL2, DSL3 and DSL4, the dimension of the first pad section PS1 in the second horizontal direction HD2 may be larger than the dimension of an electrode section ES in the second horizontal direction HD2. For example, the dimension of the electrode section ES of the fourth drain select line DSL4 in the second horizontal direction HD2 may be Wa, and the maximum dimension of the first pad section PS1 of the fourth drain select line DSL4 in the second horizontal direction HD2 may have a size of Wb, which is larger than Wa.

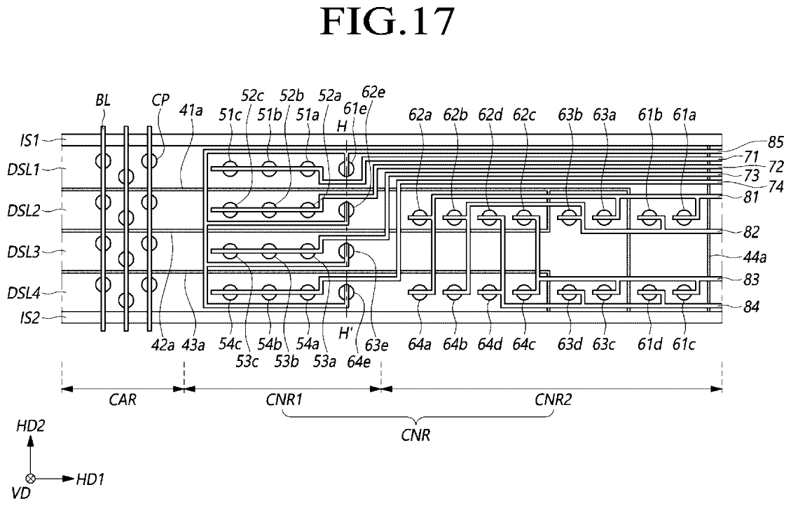

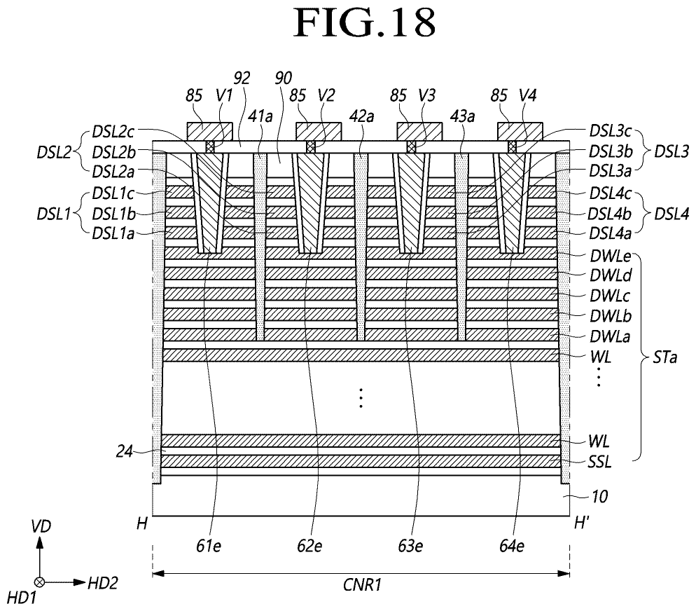

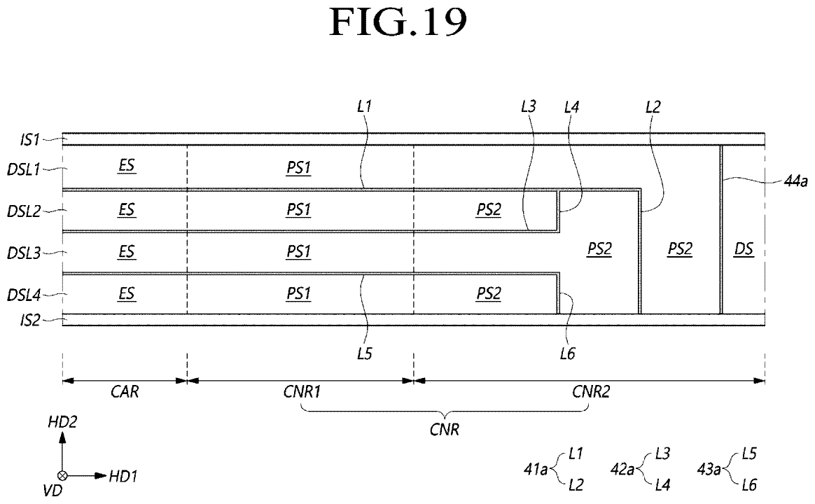

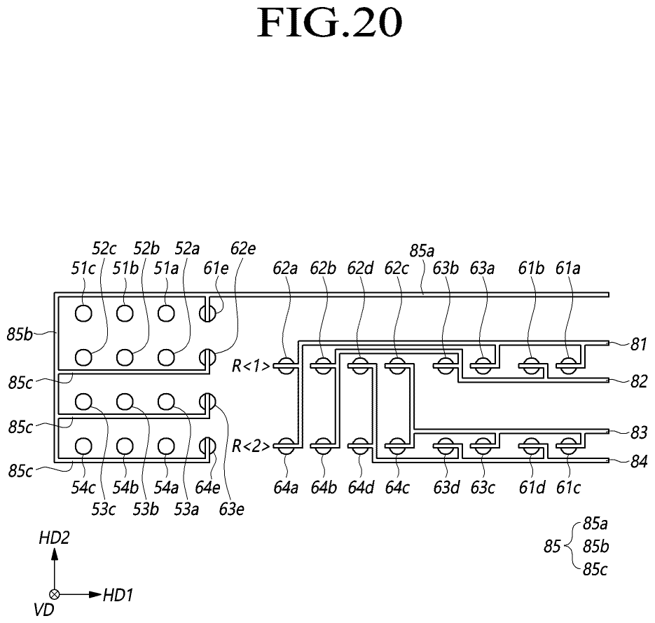

FIG. 17 is a plan view of a memory device according to embodiments of the present disclosure, FIG. 18 is a cross-sectional view taken along a line H-H′ of FIG. 17, FIG. 19 is a plan view illustrating drain select lines and isolation insulating patterns of FIG. 17, and FIG. 20 is a plan view illustrating drain contacts, dummy contacts and dummy word line connection wirings of FIG. 17. Descriptions of the same elements described above will be omitted for simplicity.

Referring to FIG. 17 to FIG. 20, a first isolation insulating pattern 41a may include a first line section L1 and a second line section L2. The first line section L1 extends in the first horizontal direction HD1 from a cell region CAR across a first connection region CNR1 into a second connection region CNR2. The second line section L2 is disposed in the second connection region CNR2, and extends from the first line section L1 to a second isolation pattern IS2 in the second horizontal direction HD2.

A second isolation insulating pattern 42a may include a third line section L3 and a fourth line section L4. The third line section L3 extends in the first horizontal direction HD1 from the cell region CAR across the first connection region CNR1 into the second connection region CNR2. The fourth line section L4 is disposed in the second connection region CNR2 and extends in the second horizontal direction HD2 from the third line section L3 to the first line section L1 of the first isolation insulating pattern 41a. The fourth line section L4 of the second isolation insulating pattern 42a is disposed closer to the first connection region CNR1 than the second line section L2 of the first isolation insulating pattern 41a.

A third isolation insulating pattern 43a may include a fifth line section L5 and a sixth line section L6. The fifth line section L5 extends in the first horizontal direction HD1 from the cell region CAR across the first connection region CNR1 into the second connection region CNR2. The sixth line section L6 is disposed in the second connection region CNR2 and extends in the second horizontal direction HD2 from the fifth line section L5 to the second isolation pattern IS2. The sixth line section L6 of the third isolation insulating pattern 43a is disposed closer to the first connection region CNR1 than the second line section L2 of the first isolation insulating pattern 41a.

A fourth isolation insulating pattern 44a may disposed in the second connection region CNR2 and extend from a first isolation pattern IS1 to the second isolation pattern IS2 in the second horizontal direction HD2. The fourth isolation insulating pattern 44a is disposed farther away from the first connection region CNR1 than the second line section L2 of the first isolation insulating pattern 41a.

Each of first, second, third and fourth drain select lines DSL1, DSL2, DSL3 and DSL4 includes an electrode section ES, a first pad section PS1 and a second pad section PS2.

Referring to FIG. 19, the electrode sections ES of the first, second, third and fourth drain select lines DSL1, DSL2, DSL3 and DSL4 are disposed in the cell region CAR. The electrode sections ES of the first, second, third and fourth drain select lines DSL1, DSL2, DSL3 and DSL4 are disposed in a line along the second horizontal direction HD2. The electrode sections ES of the second drain select lines DSL2 are disposed between the electrode sections ES of the first drain select lines DSL1 and the electrode sections ES of the third drain select lines DSL3, and the electrode sections ES of the third drain select lines DSL3 are disposed between the electrode sections ES of the second drain select lines DSL2 and the electrode sections ES of the fourth drain select lines DSL4.

The first pad sections PS1 of the first, second, third and fourth drain select lines DSL1, DSL2, DSL3 and DSL4 are disposed in the first connection region CNR1. The first pad sections PS1 of the first, second, third and fourth drain select lines DSL1, DSL2, DSL3 and DSL4 are disposed in a line along the second horizontal direction HD2. The first pad sections PS1 of the second drain select lines DSL2 are disposed between the first pad sections PS1 of the first drain select lines DSL1 and the first pad sections PS1 of the third drain select lines DSL3, and the first pad sections PS1 of the third drain select lines DSL3 are disposed between the first pad sections PS1 of the second drain select lines DSL2 and the first pad sections PS1 of the fourth drain select lines DSL4. For each of the first, second, third and fourth drain select lines DSL1, DSL2, DSL3 and DSL4, the dimension of the first pad section PS1 in the second horizontal direction HD2 may be the same as the dimension of the electrode section ES in the second horizontal direction HD2.

The second pad sections PS2 of the first, second, third and fourth drain select lines DSL1, DSL2, DSL3 and DSL4 are disposed in the second connection region CNR2.

The second pad sections PS2 of the third drain select lines DSL3 are disposed farther away from the first connection region CNR1 than the second pad sections PS2 of the second drain select lines DSL2 and the second pad sections PS2 of the fourth drain select lines DSL4. The second pad sections PS2 of the first drain select lines DSL1 are disposed farther away from the first connection region CNR1 than the second pad sections PS2 of the third drain select lines DSL3.

For each of the second and fourth drain select lines DSL2 and DSL4, the dimension of the second pad section PS2 in the second horizontal direction HD2 may be the same as the dimension of the first pad section PS1 and the electrode section ES in the second horizontal direction HD2. For each of the first and third drain select lines DSL1 and DSL3, the dimension of the second pad section PS2 in the second horizontal direction HD2 may be larger than the dimension of the first pad section PS1 and the electrode section ES in the second horizontal direction HD2.

The dimension of the second pad section PS2 of the third drain select line DSL3 in the second horizontal direction HD2 may be larger than the dimension of the second pad section PS2 of the second drain select line DSL2 in the second horizontal direction HD2 and the dimension of the second pad section PS2 of the fourth drain select line DSL4 in the second horizontal direction HD2. In an embodiment, the dimension of the second pad section PS2 of the third drain select line DSL3 in the second horizontal direction HD2 may be larger than the sum of the dimension of the first pad section PS1 of the second drain select line DSL2 in the second horizontal direction HD2, the dimension of the first pad section PS1 of the third drain select line DSL3 in the second horizontal direction HD2 and the dimension of the first pad section PS1 of the fourth drain select line DSL4 in the second horizontal direction HD2.

The dimension of the second pad section PS2 of the first drain select line DSL1 in the second horizontal direction HD2 may be larger than the dimension of the second pad section PS2 of the third drain select line DSL3 in the second horizontal direction HD2. In an embodiment, the dimension of the second pad section PS2 of the first drain select line DSL1 in the second horizontal direction HD2 may be larger than the sum of the dimension of the first pad section PS1 of the first drain select line DSL1 in the second horizontal direction HD2, the dimension of the first pad section PS1 of the second drain select line DSL2 in the second horizontal direction HD2, the dimension of the first pad section PS1 of the third drain select line DSL3 in the second horizontal direction HD2 and the dimension of the first pad section PS1 of the fourth drain select line DSL4 in the second horizontal direction HD2. In some embodiments, the dimension of the second pad section PS2 of the first drain select line DSL1 may be the same as the distance between the first and second isolation patterns IS1 and IS2 in the second horizontal direction HD2.

First, second, third and fourth dummy contacts 62a, 62b, 62c and 62d that vertically penetrate the second pad sections PS2 of the second drain select lines DSL2, first and second dummy contacts 63a and 63b that vertically penetrate the second pad sections PS2 of the third drain select lines DSL3, and first and second dummy contacts 61a and 61b that vertically penetrate the second pad sections PS2 of the first drain select lines DSL1 may be disposed in a line along the first horizontal direction HD1 to form a first row R<1>.

First, second, third and fourth dummy contacts 64a, 64b, 64c and 64d that vertically penetrate the second pad sections PS2 of the fourth drain select lines DSL4, third and fourth dummy contacts 63c and 63d that vertically penetrate the second pad sections PS2 of the third drain select lines DSL3, and third and fourth dummy contacts 61c and 61d that vertically penetrate the second pad sections PS2 of the first drain select lines DSL1 may be disposed in a line along the first horizontal direction HD1 to form a second row R<2>.

Although not illustrated in any figure, the first, second, third and fourth dummy contacts 61a, 62a, 63a and 64a are connected in common to a first dummy word line DWLa; the first, second, third and fourth dummy contacts 61b, 62b, 63b and 64b are connected in common to a second dummy word line DWLb; the first, second, third and fourth dummy contacts 61c, 62c, 63c and 64c are connected in common to a third dummy word line DWLc; and the first, second, third and fourth dummy contacts 61d, 62d, 63d and 64d are connected in common to a fourth dummy word line DWLd.

Three dummy contacts 61a, 62a and 63a, from among the dummy contacts 61a, 62a, 63a and 64a connected in common to the first dummy word line DWLa, are disposed in the first row R<1>; three dummy contacts 61b, 62b and 63b, from among the dummy contacts 61b, 62b, 63b and 64b connected in common to the second dummy word line DWLb, are disposed in the first row R<1>; three dummy contacts 61c, 63c and 64c, from among the dummy contacts 61c, 62c, 63c and 64c connected in common to the third dummy word line DWLc, are disposed in the second row R<2>; and three dummy contacts 61d, 63d and 64d, from among the dummy contacts 61d, 62d, 63d and 64d connected in common to the fourth dummy word line DWLd, are disposed in the second row R<2>.

Although embodiments of the present disclosure illustrate three dummy contacts, from among dummy contacts connected in common to one dummy word line, disposed in the same row, the present disclosure is not limited thereto. The present disclosure includes all embodiments in which at least two dummy contacts, from among dummy contacts connected in common to one dummy word line, are disposed in the same row.

Referring to FIG. 18, an electrode structure STa may be substantially the same as electrode structure ST described above and may further include an additional dummy word line DWLe that is stacked on the fourth dummy word line DWLd. A plurality of additional dummy contacts 61e, 62e, 63e and 64e may be connected to the additional dummy word line DWLe. The additional dummy contacts 61e, 62e, 63e and 64e include a first additional dummy contact 61e, a second additional dummy contact 62e, a third additional dummy contact 63e and a fourth additional dummy contact 64e.

The first additional dummy contact 61e extends in the vertical direction VD through the first drain select lines DSL1, and may be connected to the additional dummy word line DWLe. The first additional dummy contact 61e may penetrate the first pad sections PS1 of the first drain select lines DSL1.

The second additional dummy contact 62e extends in the vertical direction VD through the second drain select lines DSL2, and may be connected to the additional dummy word line DWLe. The second additional dummy contact 62e may penetrate the first pad sections PS1 of the second drain select lines DSL2.

The third additional dummy contact 63e extends in the vertical direction VD through the third drain select lines DSL3, and may be connected to the additional dummy word line DWLe. The third additional dummy contact 63e may penetrate the first pad sections PS1 of the third drain select lines DSL3.

The fourth additional dummy contact 64e extends in the vertical direction VD through the fourth drain select lines DSL4, and may be connected to the additional dummy word line DWLe. The fourth additional dummy contact 64e may penetrate the first pad sections PS1 of the fourth drain select lines DSL4.

The first, second, third and fourth additional dummy contacts 61e, 62e, 63e and 64e may be disposed in a line along the second horizontal direction HD2.

An additional dummy word line connection wiring 85 is connected in common to the first, second, third and fourth additional dummy contacts 61e, 62e, 63e and 64e. Referring to FIG. 20, the additional dummy word line connection wiring 85 may be connected to the second, third and fourth additional dummy contacts 62e, 63e and 64e by bypassing one or more drain contacts 51a to 51c, 52a to 52c, 53a to 53c and 54a to 54c. For example, the additional dummy word line connection wiring 85 includes a first line pattern 85a, a second line pattern 85b and finger patterns 85c. The first line pattern 85a may extend across the second connection region CNR2 in the first horizontal direction HD1 into the first connection region CNR1. The second line pattern 85b may extend in the second horizontal direction HD2 from the first line pattern 85a in the first connection region CNR1. The second line pattern 85b is disposed to be farther away from the second connection region CNR2 than the drain contacts 51a to 51c, 52a to 52c, 53a to 53c and 54a to 54c in the first horizontal direction HD1. The finger patterns 85c may extend from the second line pattern 85b in the first horizontal direction HD1, and may pass between neighboring or adjacent drain contacts in the second horizontal direction HD2, and may be connected to the second, third and fourth additional dummy contacts 62e, 63e and 64e, respectively.

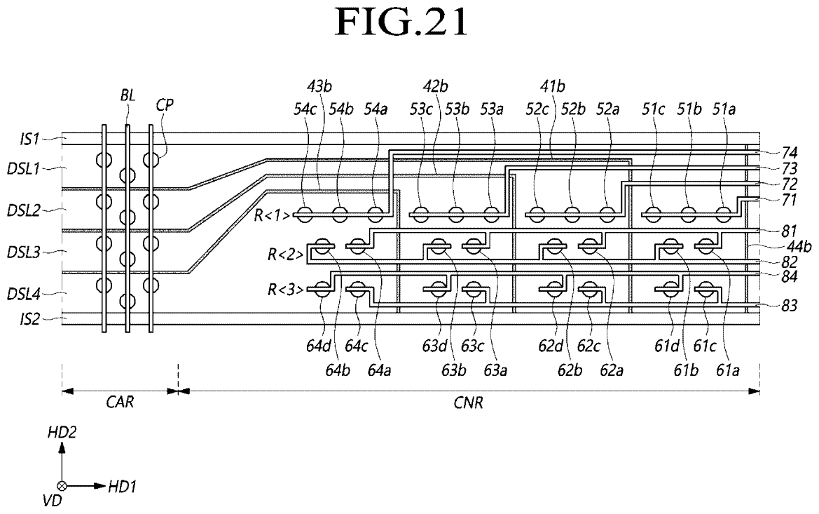

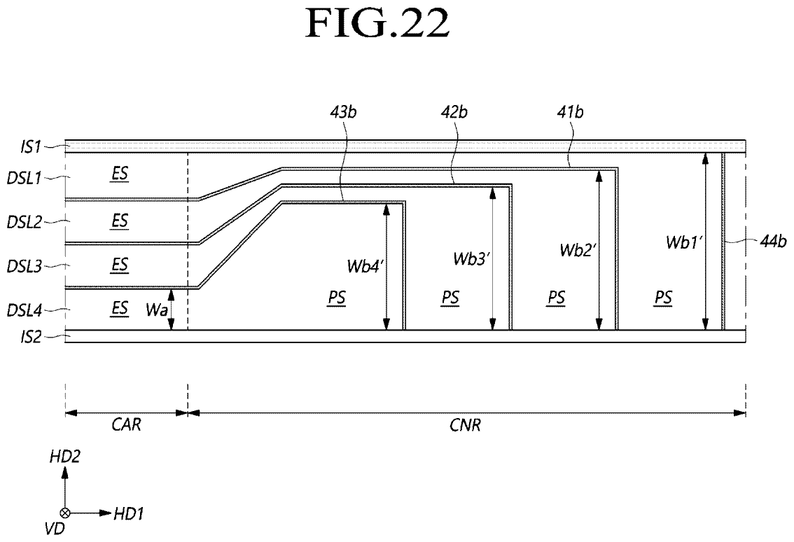

FIG. 21 is a plan view of a memory device according to embodiments of the present disclosure, and FIG. 22 is a plan view illustrating drain select lines and isolation insulating patterns of FIG. 21. Descriptions of the same elements described above will be omitted for simplicity.

Referring to FIG. 21 and FIG. 22, a memory device may include a cell region CAR and a connection region CNR that extends from the cell region CAR in a first horizontal direction HD1. Each of first, second, third and fourth drain select lines DSL1, DSL2, DSL3 and DSL4 may include an electrode section ES that is disposed in the cell region CAR and a pad section PS that is disposed in the connection region CNR.

In the cell region CAR, the electrode section ES of the first drain select line DSL1, the electrode section ES of the second drain select line DSL2, the electrode section ES of the third drain select line DSL3 and the electrode section ES of the fourth drain select line DSL4 may be disposed in a line along the second horizontal direction HD2. The electrode section ES of the first drain select line DSL1, the electrode section ES of the second drain select line DSL2, the electrode section ES of the third drain select line DSL3 and the electrode section ES of the fourth drain select line DSL4 may have the same dimension in the second horizontal direction HD2.

In the connection region CNR, the pad section PS of the first drain select line DSL1, the pad section PS of the second drain select line DSL2, the pad section PS of the third drain select line DSL3 and the pad section PS of the fourth drain select line DSL4 may be disposed in a line along the first horizontal direction HD1.

In each of the first, second, third and fourth drain select lines DSL1, DSL2, DSL3 and DSL4, the maximum dimension of the pad section PS in the second horizontal direction HD2 may be larger than the dimension of the electrode section ES in the second horizontal direction HD2. For example, in the fourth drain select line DSL4, the dimension of the electrode section ES in the second horizontal direction HD2 may be Wa, and the maximum dimension of the pad section PS in the second horizontal direction HD2 may be Wb4′, which is larger than Wa.

The maximum dimension of the pad section PS of the first drain select line DSL1 in the second horizontal direction HD2 may be larger than the maximum dimension of the pad section PS of the second drain select line DSL2 in the second horizontal direction HD2. The maximum dimension of the pad section PS of the second drain select line DSL2 in the second horizontal direction HD2 may be larger than the maximum dimension of the pad section PS of the third drain select line DSL3 in the second horizontal direction HD2. The maximum dimension of the pad section PS of the third drain select line DSL3 in the second horizontal direction HD2 may be larger than the maximum dimension of the pad section PS of the fourth drain select line DSL4 in the second horizontal direction HD2. For example, when the maximum dimension of the pad section PS of the first drain select line DSL1 in the second horizontal direction HD2 is Wb1′, the maximum dimension of the pad section PS of the second drain select line DSL2 in the second horizontal direction HD2 is Wb2′, the maximum dimension of the pad section PS of the third drain select line DSL3 in the second horizontal direction HD2 is Wb3′ and the maximum dimension of the pad section PS of the fourth drain select line DSL4 in the second horizontal direction HD2 is Wb4′, the relationship Wb1′>Wb2′>Wb3′>Wb4′ may be satisfied.

In the connection region CNR, drain contacts 51a to 51c, 52a to 52c, 53a to 53c and 54a to 54c and dummy contacts 61a to 61d, 62a to 62d, 63a to 63d and 64a to 64d may be disposed. The dummy contacts 61a to 61d, 62a to 62d, 63a to 63d and 64a to 64d may be disposed in different rows, which are arranged in the second horizontal direction HD2, from the drain contacts 51a to 51c, 52a to 52c, 53a to 53c and 54a to 54c.

The drain contacts 51a to 51c, 52a to 52c, 53a to 53c and 54a to 54c may include first drain contacts 51a to 51c, second drain contacts 52a to 52c, third drain contacts 53a to 53c and fourth drain contacts 54a to 54c. The first, second, third and fourth drain contacts 51a to 51c, 52a to 52c, 53a to 53c and 54a to 54c may be disposed in a line along the first horizontal direction HD1 to form a first row R<1>.

Among the dummy contacts 61a to 61d, 62a to 62d, 63a to 63d and 64a to 64d, dummy contacts 61a, 61b, 62a, 62b, 63a, 63b, 64a and 64b, which are connected to first and second dummy word lines, may be disposed in a line along the first horizontal direction HD1 to form a second row R<2>. Among the dummy contacts 61a to 61d, 62a to 62d, 63a to 63d and 64a to 64d, dummy contacts 61c, 61d, 62c, 62d, 63c, 63d, 64c and 64d, which are connected to third and fourth dummy word lines, may be disposed in a line along the first horizontal direction HD1 to form a third row R<3>.

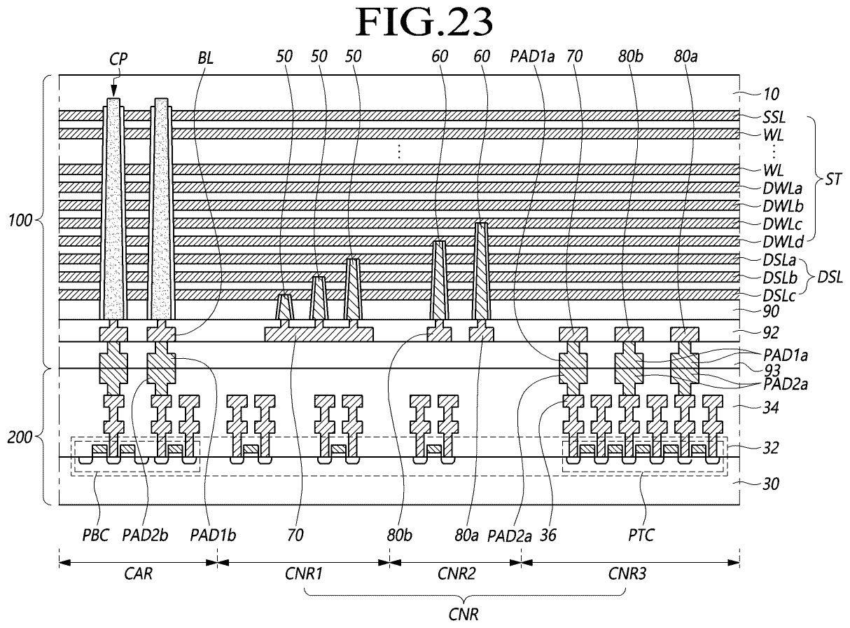

FIG. 23 is a cross-sectional view of a memory device according to embodiments of the present disclosure.

Referring to FIG. 23, a memory device may include a first chip 100 and a second chip 200. The first chip 100 may be a memory chip, and the second chip 200 may be a peripheral circuit chip.

The first chip 100 may include a first substrate 10, an electrode structure ST, drain select lines DSL, cell plugs CP, drain contacts 50, dummy contacts 60, a drain select line connection wiring 70, dummy word line connection wirings 80a and 80b, a bit line BL, first, second and third insulating layers 90, 92 and 93, first row bonding pads PAD1a, and first column bonding pads PAD1b.

The drain select line connection wiring 70, the dummy word line connection wirings 80a and 80b and the bit line BL may be disposed at the same wiring layer. The bit line BL is disposed in a cell region CAR.

The first row bonding pads PAD1a and the first column bonding pads PAD1b may be disposed in the third insulating layer 93. The lower surfaces of the first row bonding pads PAD1a and the first column bonding pads PAD1b may be exposed on the lower surface of the third insulating layer 93.

The memory device includes a connection region CNR that extends from the cell region CAR in the first horizontal direction HD1. The connection region CNR includes first, second and third connection regions CNR1, CNR2 and CNR3. Among the first, second and third connection regions CNR1, CNR2 and CNR3, the first connection region CNR1 is disposed closest to the cell region CAR in the first horizontal direction HD1, the second connection region CNR2 is disposed next closest to the cell region CAR after the first connection region CNR1, and the third connection region CNR3 is disposed farthest away from the cell region CAR.

The first column bonding pads PAD1b are disposed in the cell region CAR, and are connected to the bit line BL in the cell region CAR.

The drain contacts 50 are disposed in the first connection region CNR1, the dummy contacts 60 are disposed in the second connection region CNR2, and the first row bonding pads PAD1a are disposed in the third connection region CNR3.

The drain select line connection wiring 70 is connected to the drain contacts 50 in the first connection region CNR1, then extends from the first connection region CNR1 to the third connection region CNR3 via the second connection region CNR2, and then connects to one of the first row bonding pads PAD1a in the third connection region CNR3.

The dummy word line connection wirings 80a and 80b are connected to the dummy contacts 60, respectively, in the second connection region CNR2, then extend from the second connection region CNR2 to the third connection region CNR3, and then are connected to the first row bonding pads PAD1a, respectively, in the third connection region CNR3.

The second chip 200 may include a second substrate 30, a peripheral circuit 32, a fourth insulating layer 34 and a wiring structure 36, second row bonding pads PAD2a, and second column bonding pads PAD2b.

The peripheral circuit 32 may be disposed on the second substrate 30. The peripheral circuit 32 may control the operation of a memory cell array. The peripheral circuit 32 may include, for example, a pass transistor circuit PTC and a page buffer circuit PBC. The peripheral circuit 32 may further include a control logic and a voltage generator, but examples are not limited thereto.

The fourth insulating layer 34 may be disposed on the second substrate 30 and cover the peripheral circuit 32. The second row bonding pads PAD2a and the second column bonding pads PAD2b may be disposed in the fourth insulating layer 34. The upper surfaces of the second row bonding pads PAD2a and the second column bonding pads PAD2b may be exposed on the upper surface of the fourth insulating layer 34.

The second row bonding pads PAD2a are disposed in the third connection region CNR3, and are connected to the pass transistor circuit PTC through the wiring structure 36. The second column bonding pads PAD2b are disposed in the cell region CAR, and are connected to the page buffer circuit PBC through the wiring structure 36.

The first row bonding pads PAD1a of the first chip 100 and the second row bonding pads PAD2a of the second chip 200 may be bonded to each other. The first column bonding pads PAD1b of the first chip 100 and the second column bonding pads PAD2b of the second chip 200 may be bonded to each other.

Although, in FIG. 23, the drain contacts 50 and the dummy contacts 60 are disposed in different connection regions, embodiments of the present disclosure are not limited thereto. As described above with reference to FIG. 21 and FIG. 22, drain contacts and dummy contacts may be disposed in a single connection region.

Although, in FIG. 23, a semiconductor device includes one memory chip and one peripheral circuit chip, embodiments of the present disclosure are not limited thereto. As another example, a semiconductor device may include two or more memory chips, or may include two or more peripheral circuit chips. As still another example, at least one of semiconductor chips included in a semiconductor device may have a PUC (peripheral under cell) structure including a peripheral circuit region and a memory cell region built up on the peripheral circuit region.

While the detailed embodiments of the present disclosure are disclosed in the present disclosure, those skilled in the art will understand that various modifications, additions, and substitutions related to these embodiments are possible without departing from the scope and technical concepts of the present disclosure. Therefore, the scope of the present disclosure should not be limited to the foregoing embodiments. All changes within the meaning and range of equivalency of the claims are included within their scope.

What is claimed is:

1. A memory device comprising:
a substrate including a first connection region and a second connection region that are arranged in a first horizontal direction;
an electrode structure including a plurality of word lines that are vertically stacked on the substrate and a plurality of dummy word lines that are vertically stacked on the plurality of word lines;
a plurality of drain select lines extending in the first horizontal direction in a first drain select line layer on the electrode structure;
a plurality of drain contacts connected to the plurality of drain select lines, respectively, in the first connection region; and
a plurality of dummy contacts extending vertically through the plurality of drain select lines in the second connection region, and connected to the plurality of dummy word lines, respectively,
wherein the plurality of dummy contacts are disposed in a plurality of rows, arranged in a second horizontal direction that is perpendicular to the first horizontal direction, and dummy contacts connected in common to one of the plurality of dummy word lines are disposed in a single row parallel to the first horizontal direction.

2. The memory device according to claim 1, wherein
the substrate further includes a cell region, and
the first connection region is disposed closer to the cell region than the second connection region in the first horizontal direction.

3. The memory device according to claim 1, wherein
the plurality of dummy word lines includes first, second, third and fourth dummy word lines that are vertically stacked,
dummy contacts connected to the first and second dummy word lines are disposed in a line in a first row along the first horizontal direction, and
dummy contacts connected to the third and fourth dummy word lines are disposed in a line in a second row along the first horizontal direction.

4. The memory device according to claim 3, further comprising:
a first wiring layer disposed on the plurality of drain select lines,
wherein the first wiring layer comprises:
a plurality of drain select line connection wirings connected to the plurality of drain contacts;
a first dummy word line connection wiring connected to dummy contacts connected to the first dummy word line;
a second dummy word line connection wiring connected to dummy contacts connected to the second dummy word line;
a third dummy word line connection wiring connected to dummy contacts connected to the third dummy word line; and
a fourth dummy word line connection wiring connected to dummy contacts connected to the fourth dummy word line.

5. The memory device according to claim 4, wherein
each of the first, second, third and fourth dummy word line connection wirings includes a main line that extends in the first horizontal direction and branch lines that extend from the main line and are connected to dummy contacts,
a main line of the first dummy word line connection wiring and a main line of the second dummy word line connection wiring are disposed on both sides, respectively, of the first row, and
a main line of the third dummy word line connection wiring and a main line of the fourth dummy word line connection wiring are disposed on both sides, respectively, of the second row.

6. The memory device according to claim 4, wherein the first wiring layer further comprises a bit line.

7. The memory device according to claim 1, wherein
the plurality of dummy word lines include first and second dummy word lines,
dummy contacts connected to the first dummy word line are disposed in a line along the first horizontal direction to form a first row, and
dummy contacts connected to the second dummy word line are disposed in a line along the first horizontal direction to form a second row.

8. The memory device according to claim 7, wherein
the first row is aligned with one of the plurality of drain contacts in the first horizontal direction, and
the second row is aligned with another one of the plurality of drain contacts in the first horizontal direction.

9. The memory device according to claim 7, wherein the dummy contacts of the first row and the dummy contacts of the second row are offset from each other in the first horizontal direction.

10. The memory device according to claim 9, wherein
the plurality of drain contacts includes a first drain contact and a second drain contact adjacent to each other in the second horizontal direction,
a distance between a virtual first line that crosses the center of the first drain contact in the first horizontal direction and a virtual second line that crosses the center of the second drain contact in the first horizontal direction has a first size, and
a distance between a virtual third line that crosses the centers of the dummy contacts of the first row in the first horizontal direction and a virtual fourth line that crosses the centers of the dummy contacts of the second row in the first horizontal direction has a second size that is smaller than the first size.

11. The memory device according to claim 1, wherein
each of the plurality of drain select lines includes a first pad section that is disposed in the first connection region and a second pad section that is disposed in the second connection region,
the plurality of drain contacts are connected to the first pad sections, respectively, of the plurality of drain select lines, and
each of the plurality of dummy contacts penetrates one of the second pad sections of the plurality of drain select lines.

12. The memory device according to claim 11, wherein the second pad sections of the plurality of drain select lines are disposed in a line along the first horizontal direction.

13. The memory device according to claim 11, wherein the first pad sections of the plurality of drain select lines are disposed in a line along the second horizontal direction.

14. The memory device according to claim 11, wherein, for each of the plurality of drain select lines, a dimension of the second pad section in the second horizontal direction is larger than a dimension of the first pad section in the second horizontal direction.

15. A memory device comprising:
a substrate including a first connection region and a second connection region that are arranged in a first horizontal direction;
an electrode structure including a plurality of word lines that are vertically stacked on the substrate and a plurality of dummy word lines that are vertically stacked on the plurality of word lines;
a plurality of drain select lines extending parallel to each other in the first horizontal direction in a drain select line layer on the electrode structure, and each including a first pad section that is disposed in the first connection region and a second pad section that is disposed in the second connection region;
a plurality of drain contacts connected to first pad sections, respectively, of the plurality of drain select lines; and
a plurality of dummy contacts each extending in a vertical direction through one of second pad sections of the plurality of drain select lines, and connected to the plurality of dummy word lines, respectively,
wherein the plurality of dummy contacts are disposed in a plurality of rows arranged in a second horizontal direction perpendicular to the first horizontal direction, dummy contacts in each of the plurality of rows are disposed in a line along the first horizontal direction, and at least two of dummy contacts connected in common to one of the plurality of dummy word lines are disposed in one of the plurality of rows.

16. The memory device according to claim 15, wherein
the plurality of drain select lines include first, second, third and fourth drain select lines,
a first pad section of the second drain select line is disposed between a first pad section of the first drain select line and a first pad section of the third drain select line in the second horizontal direction,
the first pad section of the third drain select line is disposed between the first pad section of the second drain select line and a first pad section of the fourth drain select line in the second horizontal direction,
a second pad section of the third drain select line is disposed farther away from the first connection region in the first horizontal direction than a second pad section of the second drain select line and a second pad section of the fourth drain select line, and
a second pad section of the first drain select line is disposed farther away from the first connection region than the second pad section of the third drain select line in the first horizontal direction.

17. The memory device according to claim 16, wherein
for each of the second and fourth drain select lines, a dimension of the second pad section in the second horizontal direction is the same as a dimension of the first pad section in the second horizontal direction, and
for each of the first and third drain select lines, the dimension of the second pad section in the second horizontal direction is larger than the dimension of the first pad section in the second horizontal direction.

18. The memory device according to claim 17, wherein the dimension of the second pad section in the second horizontal direction in each of the first and third drain select lines is larger than the dimension of the second pad section of the second drain select line in the second horizontal direction and the dimension of the second pad section of the fourth drain select line in the second horizontal direction.

19. The memory device according to claim 17, wherein the dimension of the second pad section of the first drain select line in the second horizontal direction is larger than the dimension of the second pad section of the third drain select line in the second horizontal direction.

20. The memory device according to claim 16,
wherein the plurality of dummy word lines include first, second, third and fourth dummy word lines,
wherein the plurality of dummy contacts comprise:
first dummy contacts extending vertically through the second pad section of the first drain select line, and connected to the first, second, third and fourth dummy word lines, respectively;
second dummy contacts extending vertically through the second pad section of the second drain select line, and connected to the first, second, third and fourth dummy word lines, respectively;
third dummy contacts extending vertically through the second pad section of the third drain select line, and connected to the first, second, third and fourth dummy word lines, respectively; and
fourth dummy contacts extending vertically through the second pad section of the fourth drain select line, and connected to the first, second, third and fourth dummy word lines, respectively,
wherein first dummy contacts connected to the first and second dummy word lines, third dummy contacts connected to the first and second dummy word lines and the second dummy contacts are disposed in a first row along the first horizontal direction, and
wherein first dummy contacts connected to the third and fourth dummy word lines, third dummy contacts connected to the third and fourth dummy word lines and the fourth dummy contacts are disposed in a second row along the first horizontal direction.

21. The memory device according to claim 15, further comprising:
a plurality of additional dummy contacts each penetrating first pad sections of the plurality of drain select lines, and connected in common to one of the plurality of dummy word lines,
wherein the plurality of additional dummy contacts are disposed in a row along the second horizontal direction.

22. The memory device according to claim 21, wherein the plurality of additional dummy contacts are disposed closer in the first horizontal direction to the second connection region than the plurality of drain contacts.

23. The memory device according to claim 21, further comprising:
a first wiring layer on the plurality of drain select lines,
wherein the first wiring layer includes an additional dummy word line connection wiring that is connected in common to the plurality of additional dummy contacts,
wherein the additional dummy word line connection wiring comprises:
a first line section extending from the second connection region to the first connection region in the first horizontal direction;
a second line section extending in the second horizontal direction from the first line section; and
a plurality of finger sections, passing between adjacent rows of drain contacts, that are arranged in the second horizontal direction and extend in the first horizontal direction from the second line section to connect to the plurality of additional dummy contacts, respectively, and
wherein the second line section is disposed in the first horizontal direction farther away from the second connection region than the plurality of drain contacts.

24. A memory device comprising:
a substrate including a cell region and a connection region that extends in a row direction from the cell region;
an electrode structure including a plurality of word lines that are vertically stacked on the substrate and a plurality of dummy word lines that are vertically stacked on the plurality of word lines;
a plurality of drain select lines extending in the row direction in a first drain select line layer on the electrode structure, and each including an electrode section that is disposed in the cell region and a pad section that is disposed in the connection region;
a plurality of drain contacts connected to pad sections of the plurality of drain select lines, respectively, in the connection region; and
a plurality of dummy contacts extending vertically through the pad sections of the plurality of drain select lines in the connection region, and connected to the plurality of dummy word lines, respectively,
wherein the plurality of dummy contacts are disposed in a different row from the plurality of drain contacts when viewed in a plan view.

25. The memory device according to claim 24, wherein the pad sections of the plurality of drain select lines are disposed in a line along the row direction.

26. The memory device according to claim 24, wherein, in each of the plurality of drain select lines, a dimension of the pad section in a column direction is larger than a dimension of the electrode section in the column direction.

27. The memory device according to claim 24, wherein
the plurality of dummy word lines include first, second, third and fourth dummy word lines,
dummy contacts connected to the first and second dummy word lines are disposed in a line along the row direction to form a first row, and
dummy contacts connected to the third and fourth dummy word lines are disposed in a line along the row direction to form a second row.
